(19) United States
(12) Patent Application Publication
(10) Pub. No.: US 2026/0013311 A1
(43) Pub. Date: Jan. 8, 2026

(54) DISPLAY DEVICE AND ELECTRONIC DEVICE INCLUDING THE SAME

(71) Applicant: Samsung Display Co., LTD., Yongin-si (KR)

(72) Inventors: Sang Jo KIM, Yongin-si (KR); Byung Ju LEE, Yongin-si (KR); Kwan Jae LEE, Yongin-si (KR); Su Jeong KIM, Yongin-si (KR); Sang Tae LEE, Yongin-si (KR)

(73) Assignee: Samsung Display Co., LTD., Yongin-si (KR)

(21) Appl. No.: 19/073,357

(22) Filed: Mar. 7, 2025

(30) Foreign Application Priority Data
Jul. 4, 2024 (KR) 10-2024-0088032

(51) Int. Cl. H10H 29/80; H01L 25/075; H10H 29/49

(52) U.S. Cl. CPC H10H 29/962; H01L 25/0756; H10H 29/49; H10H 29/8323; H10H 29/8421; H01L 25/0753

(57) ABSTRACT

A display device according to an embodiment includes a lower substrate, a first bonding electrode disposed on the lower substrate, a first light emitting element disposed on the first bonding electrode, a second bonding electrode disposed on the first light emitting element, and a second light emitting element disposed on the second bonding electrode, the second bonding electrode includes a first distributed Bragg reflector including at least one pair of a first transparent conductive layer and a second transparent conductive layer having different refractive indices that are alternately stacked.

### CROSS-REFERENCE TO RELATED APPLICATION(S)

This application claims priority to and benefits of Korean Patent Application No. 10-2024-0088032 under 35 U.S.C. § 119 filed on Jul. 4, 2024, in the Korean Intellectual Property Office, the entire contents of which are incorporated herein by reference.

### BACKGROUND

### 1. Technical Field

Embodiments relate to a display device and an electronic device including the same.

### 2. Description of the Related Art

With the advance of an information-oriented society, more and more demands are placed on display devices for displaying images in various ways. Along with this trend, various types of display devices including a light emitting display device are being developed. The light emitting display device may include pixels including light emitting elements.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device including light emitting elements stacked on a lower substrate, and an electronic device including the display device.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, there is provided a display device that may include, a lower substrate; a first bonding electrode disposed on the lower substrate; a first light emitting element disposed on the first bonding electrode; a second bonding electrode disposed on the first light emitting element; and a second light emitting element disposed on the second bonding electrode, wherein the second bonding electrode may include a first distributed Bragg reflector including at least one pair of a first transparent conductive layer and a second transparent conductive layer having different refractive indices that are alternately stacked.

In an embodiment, the first transparent conductive layer and the second transparent conductive layer may include a same transparent conductive oxide, and the second transparent conductive layer may have a higher concentration of pores compared to pores of the first transparent conductive layer.

In an embodiment, the first transparent conductive layer may include indium tin oxide (ITO), and the second transparent conductive layer may include porous ITO.

In an embodiment, the first transparent conductive layer may include zinc oxide (ZnO) or indium zinc oxide (IZO), and the second transparent conductive layer may include porous ZnO or porous IZO.

In an embodiment, the first transparent conductive layer and the second transparent conductive layer may further include gallium doped into the same transparent conductive oxide.

In an embodiment, the first light emitting element may emit light of a first color, the second light emitting element may emit light of a second color, and the first distributed Bragg reflector may transmit light of the first color and may reflect light of the second color.

In an embodiment, the display device may further include a third bonding electrode disposed on the second light emitting element, and a third light emitting element disposed on the third bonding electrode, and the third bonding electrode may include a second distributed Bragg reflector including at least one pair of a third transparent conductive layer and a fourth transparent conductive layer having different refractive indices that are alternately stacked.

In an embodiment, the third light emitting element may emit light of a third color, and the second distributed Bragg reflector may transmit light of the first color and light of the second color and may reflect light of the third color.

In an embodiment, the third transparent conductive layer and the fourth transparent conductive layer may include the same transparent conductive oxide, and the fourth transparent conductive layer may have a higher concentration of pores than pores of the third transparent conductive layer.

In an embodiment, the third transparent conductive layer may include ITO, and the fourth transparent conductive layer may include porous ITO.

In an embodiment, the third transparent conductive layer may include ZnO or IZO, and the fourth transparent conductive layer may include porous ZnO or porous IZO.

In an embodiment, the third transparent conductive layer and the fourth transparent conductive layer may further include gallium doped into the same transparent conductive oxide.

In an embodiment, the second transparent conductive layer and the fourth transparent conductive layer may be formed as porous films including the same transparent conductive oxide.

In an embodiment, at least one of porosity of the second transparent conductive layer and a porosity of the fourth transparent conductive layer, a number of pairs of the first transparent conductive layer and the second transparent conductive layer and a number of pairs of the third transparent conductive layer and the fourth transparent conductive layer, and a pair thickness of the first transparent conductive layer and the second transparent conductive layer and a pair thickness of the third transparent conductive layer and the fourth transparent conductive layer may be different.

In an embodiment, the first bonding electrode may include a bonding metal layer including a bonding metal and a reflective layer disposed above the bonding metal layer.

In an embodiment, the display device may further include a first pixel electrode electrically connected to a first semiconductor layer of the first light emitting element through the first bonding electrode, an interlayer insulating layer disposed between the first light emitting element and the second bonding electrode, a second pixel electrode electrically connected to a first semiconductor layer of the second light emitting element through the second bonding electrode, and a common electrode electrically connected to a second semiconductor layer of the first light emitting element and a second semiconductor layer of the second light emitting element.

In an embodiment, the first light emitting element and the second light emitting element may be connected to the second bonding electrode.

In an embodiment, the display device may further include a first pixel electrode electrically connected to a first semiconductor layer of the first light emitting element through the first bonding electrode, a second pixel electrode electrically connected to a first semiconductor layer of the second light emitting element, and a common electrode electrically connected to a second semiconductor layer of the first light emitting element and a second semiconductor layer of the second light emitting element through the second bonding electrode.

In an embodiment, the display device may further include a connection electrode disposed on the second light emitting element and electrically connecting the first semiconductor layer of the second light emitting element to the second pixel electrode.

In an embodiment, the second bonding electrode may be disposed directly on the first light emitting element, and the second light emitting element may be disposed directly on the second bonding electrode.

According to an aspect of the disclosure, there is provided an electronic device that may include a display device, the display device including; a lower substrate; a first bonding electrode disposed on the lower substrate; a first light emitting element disposed on the first bonding electrode; a second bonding electrode disposed on the first light emitting element; and a second light emitting element disposed on the second bonding electrode, wherein the second bonding electrode may include a first distributed Bragg reflector including at least one pair of a first transparent conductive layer and a second transparent conductive layer having different refractive indices that are alternately stacked.

The first transparent conductive layer and the second transparent conductive layer may include a same transparent conductive oxide, and the second transparent conductive layer may have a higher concentration of pores compared to pores of the first transparent conductive layer.

The first transparent conductive layer may include indium tin oxide (ITO), and the second transparent conductive layer includes porous ITO.

The display device according to embodiments may include the light emitting elements stacked on the lower substrate and bonding electrodes disposed below the respective light emitting elements. In embodiments, the bonding electrode disposed on at least one light emitting element may include a distributed Bragg reflector including transparent conductive layers of different refractive indices. According to embodiments, light generated in the light emitting elements may be appropriately emitted toward the top of the display device, and the reliability of the bonding electrodes and the display device including them may be improved.

However, effects according to the embodiments of the disclosure are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to an embodiment;

FIG. 2 is a schematic plan view illustrating a display area of a display device according to an embodiment;

FIG. 3 is a schematic cross-sectional view illustrating a display device according to an embodiment;

FIG. 4 is a schematic cross-sectional view illustrating a display device according to an embodiment;

FIG. 5 is a schematic plan view illustrating a display area of a display device according to an embodiment;

FIG. 6 is a schematic cross-sectional view showing a display device according to an embodiment;

FIG. 7 is a schematic cross-sectional view showing a display device according to an embodiment;

FIG. 8 is a schematic plan view illustrating a display area of a display device according to an embodiment;

FIG. 9 is a schematic plan view illustrating a display area of a display device according to an embodiment;

FIG. 10 is a schematic cross-sectional view showing a bonding electrode according to an embodiment;

FIG. 11 is a schematic cross-sectional view showing a bonding electrode according to an embodiment;

FIG. 12 is a schematic cross-sectional view showing a bonding electrode according to an embodiment;

FIG. 13 is a graph illustrating the reflection characteristics of a distributed Bragg reflector based on the number of pairs and the film forming condition of transparent conductive layers;

FIG. 14 is a graph illustrating the reflection characteristics of a distributed Bragg reflector based on the number of pairs of transparent conductive layers;

FIG. 15 is a diagram illustrating a smart watch including a display device according to an embodiment;

FIGS. 16 and 17 illustrate a head mounted display including a display device according to an embodiment;

FIG. 18 illustrates a head mounted display including a display device according to an embodiment;

FIG. 19 is a diagram illustrating a dashboard of an automobile and a center fascia including display devices according to an embodiment; and

FIG. 20 is a diagram illustrating a transparent display device including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Features of each of various embodiments of the disclosure may be partially or entirely combined with each other, and respective embodiments may be implemented independently of each other or may be implemented together.

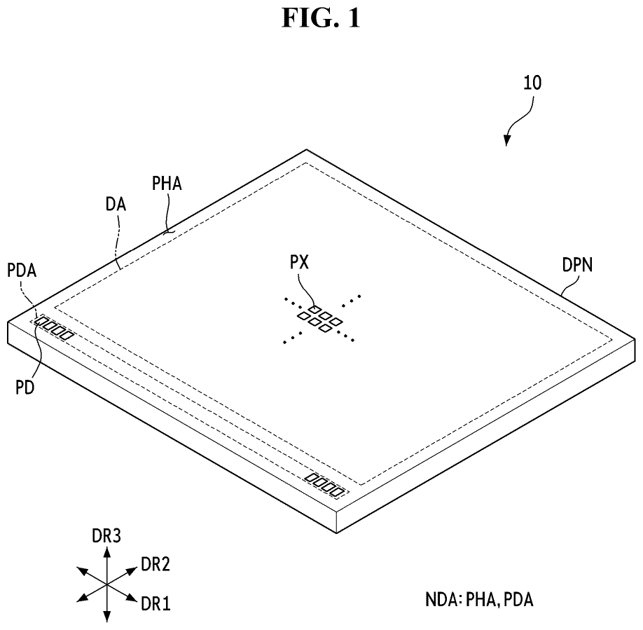

FIG. 1 is a schematic perspective view illustrating a display device according to an embodiment.

Referring to FIG. 1, a display device 10 may be a device for displaying a moving image or a still image, and may be used as a display screen for various products such as electronic devices. For example, the display device 10 may be included in various electronic devices such as televisions, laptop computers, monitors, billboards and the Internet of Things (IoT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs) and used as a display screen for the electronic devices. Additionally, the display device 10 may be applied to or included in a virtual reality (VR) device, an augmented reality (AR) device, or the like within the spirit and the scope of the disclosure.

In an embodiment, the display device 10 may be a light emitting display device including light emitting elements. For example, the display device 10 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display using an ultra-small light emitting diode such as a micro light emitting diode (micro LED) or a nano light emitting diode (nano LED).

Hereinafter, embodiments in which the display device 10 is a light emitting display device including a micro light emitting diode or a nano light emitting diode will be described. However, the type or size of the light emitting element according to embodiments is not limited thereto.

The display device 10 may include a display panel DPN including a display area DA and a non-display area NDA. In an embodiment, the display panel DPN may have a quadrilateral planar shape, but is not limited thereto. For example, the display panel DPN may have a polygonal shape other than a quadrilateral shape, a circular shape, an elliptical shape, or an irregular shape in plan view. In FIG. 1, a first direction DR1, a second direction DR2, and a third direction DR3 are indicated. In an embodiment, the first direction DR1, the second direction DR2, and the third direction DR3 may be the horizontal direction, the vertical direction, and the thickness direction of the display panel DPN, respectively.

The display area DA may be an area in which the pixels PX are disposed, and may be an area in which an image is displayed by the pixels PX. For example, the pixels PX and wires (or some of the wires) connected to the pixels PX may be disposed in the display area DA. In describing embodiments, the term “connect” may include electrical connection and/or physical connection. Although FIG. 1 illustrates an embodiment in which the display area DA has a quadrilateral planar shape, the shape of the display area DA is not limited thereto.

The pixels PX may have a quadrilateral planar shape such as a rectangular shape or a rhombic shape, but the disclosure is not limited thereto. For example, the pixels PX may have another polygonal shape (for example, a hexagonal shape or diamond shape), a circular shape, an elliptical shape, or other planar shapes.

In an embodiment, each of the pixels PX of the display device 10 may include light emitting elements that emit light of different colors. For example, each pixel PX may include a first light emitting element that emits light of a first color, a second light emitting element that emits light of a second color, and a third light emitting element that emits light of a third color. In an embodiment, the light of the first color, the light of the second color, and the light of the third color may be red light, blue light, and green light, respectively, but are not limited thereto. The number, type, and/or arrangement structure of the light emitting elements disposed in each pixel PX may be variously changed according to embodiments.

In an embodiment, each pixel PX may include pixel circuits individually connected to the light emitting elements. Accordingly, each of the light emitting elements may be driven independently and/or individually. For example, each pixel PX may include a first pixel circuit electrically connected to the first light emitting element, a second pixel circuit electrically connected to the second light emitting element, and a third pixel circuit electrically connected to the third light emitting element.

The non-display area NDA may be an area where an image is not displayed. The non-display area NDA may be disposed around the display area DA. In one example, the non-display area NDA may be disposed at the edge of the display panel DPN to surround or to be adjacent to the display area DA.

The non-display area NDA may include a pad area PDA and a peripheral area PHA. Wires (or portions of the wires) connected to the pixels PX, and pads PD may be disposed in the non-display area NDA. In an embodiment, the non-display area NDA may further include a common voltage supply area disposed around the display area DA, for example, between the display area DA and the pad area PDA.

The pads PD may be disposed in the pad area PDA. The pads PD may be connected to an external circuit board. For example, the pads PD may be electrically connected to circuit pads on the circuit board through a conductive connection member such as a wire. The pads PD may be electrically connected to the pixels PX. For example, the pads PD may include signal pads and power pads that are electrically connected to the light emitting elements and the pixel circuits of the pixels PX. In an embodiment, the pixels PX and the pads PD may be electrically connected to each other through circuit elements and/or wires formed on a semiconductor circuit board or the like of the display panel DPN. Through the pads PD, driving signals and driving voltages for driving the pixels PX may be supplied from the external circuit board to the display device 10 (or the display panel DPN).

The peripheral area PHA may be the remaining area excluding the pad area PDA in the non-display area NDA. The peripheral area PHA may surround or to be adjacent to the display area DA. Wires that connect the pixels PX to the pads PD may pass through the peripheral area PHA.

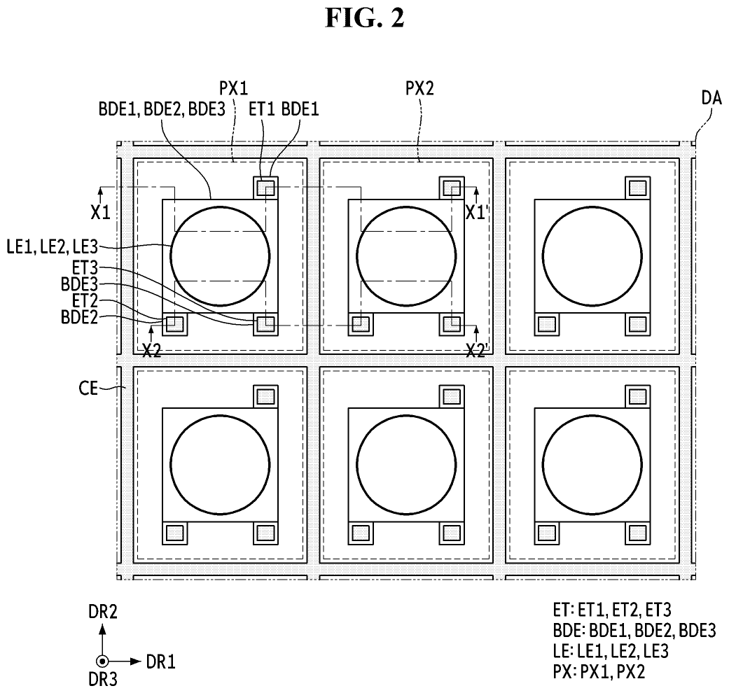

FIG. 2 is a schematic plan view illustrating a display area of a display device according to an embodiment. For example, FIG. 2 schematically shows a part of the display area DA shown in FIG. 1.

Referring to FIGS. 1 and 2, the pixels PX including a first pixel PX1 and a second pixel PX2 may be disposed in the display area DA. The pixels PX may be arranged or disposed in a stripe shape or other shapes in the display area DA.

The first pixel PX1 and the second pixel PX2 may refer to any two arbitrary pixels PX. For example, in FIG. 2, two pixels PX adjacent to each other in the first direction DR1 are referred to as the first pixel PX1 and the second pixel PX2, respectively. The pixels PX of the display area DA may have substantially the same or similar structure, and may be independently and/or individually driven by driving signals supplied to the respective pixels PX.

In an embodiment, the pixels PX may have a quadrilateral planar shape such as a rectangular shape or a rhombic shape, but the disclosure is not limited thereto. For example, the pixels PX may have another polygonal shape (for example, a hexagonal shape or diamond shape), a circular shape, an elliptical shape, or other planar shapes.

Each pixel PX may include light emitting elements LE. In one example, each pixel PX may include a first light emitting element LE1, a second light emitting element LE2, and a third light emitting element LE3 that overlap each other in plan view.

FIG. 2 illustrates the approximate positions or shapes of the first light emitting element LE1, the second light emitting element LE2, and the third light emitting element LE3, and the embodiments are not limited to the illustrated form. For example, in FIG. 2, the first light emitting element LE1, the second light emitting element LE2, and the third light emitting element LE3 are shown as having the same size and completely overlapping each other, but the embodiments are not limited thereto. In one example, in plan view, the size of at least one of the first light emitting element LE1, the second light emitting element LE2, or the third light emitting element LE3 may differ from the size of another.

The first light emitting element LE1, the second light emitting element LE2, and the third light emitting element LE3 may emit light of different colors. For example, the first light emitting element LE1 may be a red light emitting element that emits light of the first color, for example, red. The second light emitting element LE2 may be a green light emitting element that emits light of the second color, for example, green. The third light emitting element LE3 may be a blue light emitting element that emits light of the third color, for example, blue. However, the embodiments are not limited thereto. For example, the number or type of the light emitting elements LE disposed in each pixel PX may be variously changed.

The light emitting elements LE may have a circular shape, a quadrilateral shape, a polygonal shape other than a quadrilateral shape, or another planar shape. For example, FIG. 2 illustrates an embodiment in which the light emitting elements LE have a circular planar shape, but the shape of the light emitting elements LE may be variously changed.

In an embodiment, the light emitting elements LE may be micro light emitting diodes (micro LEDs) having a small size in the micrometer (μm) range. For example, each of the light emitting elements LE may be a micro LED having a length (for example, horizontal length or diameter) in the first direction DR1, a length (for example, vertical length or diameter) in the second direction DR2, and a length (for example, thickness or height) in the third direction DR3, which are several micrometers to several hundreds of micrometers, respectively. In an embodiment, the length in the first direction DR1, the length in the second direction DR2, and the length in the third direction DR3 of each of the light emitting elements LE may each be 100 μm or less. However, the embodiments are not limited thereto, and the size of the light emitting elements LE may be variously changed.

Each pixel PX may further include electrodes electrically connected to the light emitting elements LE. For example, each pixel PX may include bonding electrodes BDE (also referred to as “electrodes”) and pixel electrodes ET that are individually connected to the light emitting elements LE. In an embodiment, the pixel electrodes ET of each pixel PX may be connected to the light emitting elements LE through the bonding electrodes BDE of the corresponding pixel PX. However, the embodiments are not limited thereto. For example, at least one pixel electrode ET may be connected to the light emitting element LE through a separate connection electrode, or may be directly connected to the light emitting element LE.

In an embodiment, each pixel PX may include a first bonding electrode BDE1 (also referred to as “first electrode”), a second bonding electrode BDE2 (also referred to as “second electrode”), and a third bonding electrode BDE3 (also referred to as “third electrode”) that overlap each other in plan view. The bonding electrodes BDE may overlap the light emitting elements LE. For example, the first bonding electrode BDE1, the second bonding electrode BDE2, and the third bonding electrode BDE3 of the first pixel PX1 may overlap the first light emitting element LE1, the second light emitting element LE2, and the third light emitting element LE3 of the first pixel PX1 in plan view. In an embodiment, the bonding electrodes BDE may have a size larger than the light emitting elements LE in plan view, and may be disposed in an area that may include a region where the light emitting elements LE are disposed and its surrounding region, but are not limited thereto. The bonding electrodes BDE may have the same shape as the light emitting elements LE or may have a different shape from the light emitting elements LE. FIG. 2 illustrates an embodiment in which the light emitting elements LE have a circular planar shape and the bonding electrodes BDE have a quadrilateral planar shape, but the shape of each of the light emitting elements LE and the bonding electrodes BDE may be variously changed according to embodiments.

In an embodiment, the bonding electrodes BDE may have generally or substantially the same shape and/or size as each other, and may overlap each other in a region where the light emitting elements LE are disposed. In one example, the bonding electrodes BDE may have substantially the same shape and/or size, except for the portions connected to the respective pixel electrodes ET, and may overlap each other in plan view.

For example, the first bonding electrode BDE1 may have a substantially quadrilateral planar shape and may protrude to overlap a first pixel electrode ET1 in a region where the first pixel electrode ET1 is disposed. In a region where the first pixel electrode ET1 and the first bonding electrode BDE1 overlap, the first pixel electrode ET1 and the first bonding electrode BDE1 may be electrically connected to each other. The second bonding electrode BDE2 may have a substantially quadrilateral planar shape and may protrude to overlap a second pixel electrode ET2 in a region where the second pixel electrode ET2 is disposed. In a region where the second pixel electrode ET2 and the second bonding electrode BDE2 overlap, the second pixel electrode ET2 and the second bonding electrode BDE2 may be electrically connected to each other. The third bonding electrode BDE3 may have a substantially quadrilateral planar shape, and may protrude to overlap a third pixel electrode ET3 in a region where the third pixel electrode ET3 is disposed. In a region where the third pixel electrode ET3 and the third bonding electrode BDE3 overlap, the third pixel electrode ET3 and the third bonding electrode BDE3 may be electrically connected to each other.

The pixel electrodes ET may overlap the respective bonding electrodes BDE, and may not overlap each other in plan view. The first pixel electrode ET1 may overlap a portion of the first bonding electrode BDE1. The second pixel electrode ET2 may overlap a portion of the second bonding electrode BDE2. The third pixel electrode ET3 may overlap a portion of the third bonding electrode BDE3.

In an embodiment, the pixel electrodes ET may not overlap the light emitting elements LE. In one example, the pixel electrodes ET may be disposed around a region where the light emitting elements LE are disposed, and may not overlap the light emitting elements LE in plan view.

However, the embodiments are not limited thereto, and the shape, position, and/or arrangement order of the pixel electrodes ET disposed in each pixel PX may be variously changed according to embodiments. For example, in an embodiment, at least one pixel electrode ET may overlap at least one light emitting element LE.

The pixel electrodes ET may be electrically connected to the light emitting elements LE through the bonding electrodes BDE. For example, the first pixel electrode ET1 may be electrically connected to the first light emitting element LE1 through the first bonding electrode BDE1. The second pixel electrode ET2 may be electrically connected to the second light emitting element LE2 through the second bonding electrode BDE2. The third pixel electrode ET3 may be electrically connected to the third light emitting element LE3 through the third bonding electrode BDE3. However, the arrangement structure or connection structure of the pixel electrodes ET and the light emitting elements LE may be variously changed according to embodiments.

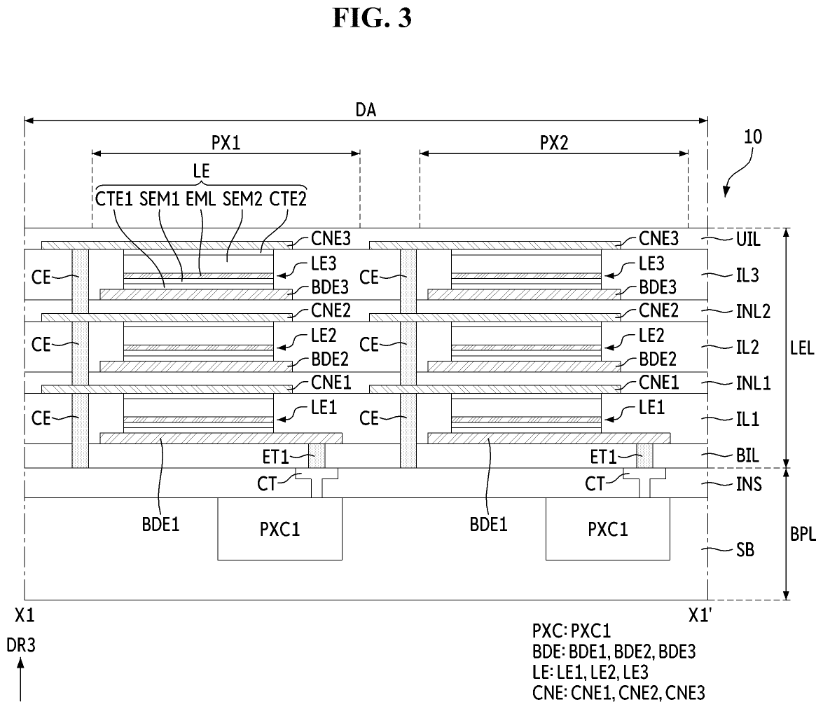

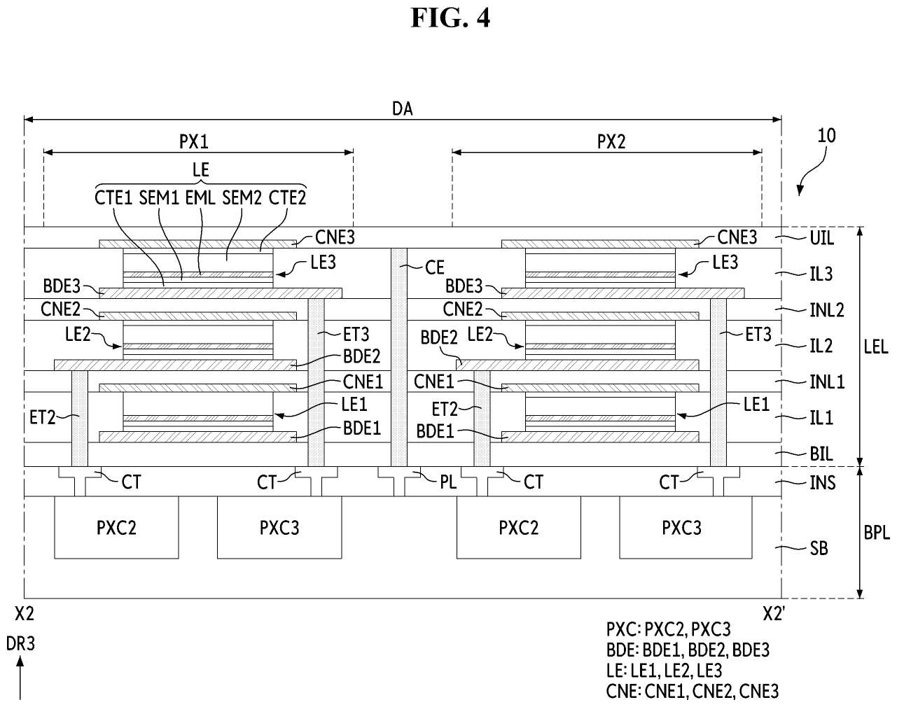

The pixel electrodes ET may be electrically connected to pixel circuits (for example, pixel circuits PXC of FIGS. 3 and 4) of a lower substrate disposed below a light emitting element layer including the light emitting elements LE. The pixel electrodes ET may electrically connect the light emitting elements LE to the respective pixel circuits PXC.

A common electrode CE (or a common voltage line) may be further disposed in the display area DA. In an embodiment, the common electrode CE may include openings corresponding to the pixels PX and may be disposed between the pixels PX. For example, the common electrode CE may have a mesh shape surrounding the pixels PX in plan view. However, the embodiments are not limited thereto, and the shape, position, and/or number of the common electrode CE may be variously changed according to embodiments.

In an embodiment, the common electrode CE may be electrically connected to the light emitting elements LE through connection electrodes (for example, connection electrodes CNE of FIGS. 3 and 4) that are in contact with and/or connected to the light emitting elements LE. However, the arrangement structure or connection structure of the common electrode CE and the light emitting elements LE may be variously changed according to embodiments.

According to embodiments, by disposing the light emitting elements LE of each pixel PX in an overlapping manner, a pixel region in which each pixel PX is disposed may be utilized more efficiently. For example, the light emitting elements LE having a larger size may be disposed in each defined pixel region. As a result, the ratio of the volume to the surface area of each light emitting element LE may be increased, and the efficiency (for example, luminous efficiency) of the light emitting elements LE may be improved.

FIG. 3 is a schematic cross-sectional view illustrating a display device according to an embodiment. FIG. 4 is a schematic cross-sectional view illustrating a display device according to an embodiment. For example, FIG. 3 shows an embodiment of a schematic cross section for a portion of the display area DA corresponding to line X1-X1′ in FIG. 2, and FIG. 4 shows an embodiment of a schematic cross section for a portion of the display area DA corresponding to line X2-X2′ in FIG. 2.

Referring to FIGS. 1 to 4, the display device 10 may include a lower substrate BPL (or a thin film transistor substrate) and a light emitting element layer LEL disposed on the lower substrate BPL. FIGS. 3 and 4 illustrate the display device 10 with a light emitting diode on silicon (LEDoS) structure in which light emitting diodes are disposed as the light emitting elements LE on the lower substrate BPL (for example, a backplane substrate formed as a semiconductor circuit board) formed by a semiconductor process using a silicon wafer. However, the embodiments are not limited thereto. For example, the lower substrate BPL may be a backplane substrate of a different type or structure. Additionally, the embodiments may be applied to display devices of different types and/or structures, or may be applied to devices of different types and/or structures, such as lighting devices.

In an embodiment, the display device 10 may further include an additional component. In one example, the display device 10 may further include at least one of a color filter layer, a protective layer, or an optical structure (for example, a microlens overlapping the light emitting elements LE of each pixel PX) disposed on the light emitting element layer LEL.

The lower substrate BPL may include a base substrate SB, the pixel circuits PXC, and the pads PD of FIG. 1. In an embodiment, the lower substrate BPL may further include contact terminals CT and an insulating layer INS disposed on the pixel circuits PXC.

The lower substrate BPL may further include wires electrically connected to the pixels PX and the pads PD. For example, the lower substrate BPL may include signal lines (for example, scan lines and data lines) electrically connected to the pixels PX, and power lines (for example, a pixel power line for transmitting a first driving voltage (for example, pixel voltage or anode voltage) to the pixels PX, and a common voltage line PL for transmitting a second driving voltage (for example, common voltage or cathode voltage) to the pixels PX). The pixel circuits PXC, the contact terminals CT, the wires, and the pads PD may be disposed or formed on the base substrate SB.

In an embodiment, the lower substrate BPL may be formed through a semiconductor process using a silicon wafer. For example, the base substrate SB may be a silicon wafer. In an embodiment, the base substrate SB may be made of monocrystalline silicon.

The pixel circuits PXC may be disposed on the lower substrate BPL to correspond to the respective pixel areas where the respective pixels PX are disposed. In an embodiment, each of the pixel circuits PXC may include a complementary metal oxide semiconductor (CMOS) circuit formed using a semiconductor process. For example, each of the pixel circuits PXC may include at least one transistor and at least one capacitor formed through a semiconductor process.

In an embodiment, each pixel PX may include the pixel circuits PXC electrically connected to the light emitting elements LE of the corresponding pixel PX. For example, each pixel PX may include a first pixel circuit PXC1 electrically connected to the first light emitting element LE1, a second pixel circuit PXC2 electrically connected to the second light emitting element LE2, and a third pixel circuit PXC3 electrically connected to the third light emitting element LE3. The first pixel circuit PXC1, the second pixel circuit PXC2, and the third pixel circuit PXC3 may control a driving current flowing through the first light emitting element LE1, the second light emitting element LE2, and the third light emitting element LE3 in response to respective driving signals inputted from the outside.

FIGS. 3 and 4 illustrate the schematic shapes and positions of the pixel circuits PXC included in the first pixel PX1 and the second pixel PX2 and the contact terminals CT electrically connected to the pixel circuits PXC, as an example of elements disposed inside the lower substrate BPL. FIGS. 3 and 4 also illustrate the schematic shape and position of the common voltage line PL electrically connected to the light emitting elements LE of the pixels PX through the common electrode CE, as an example of wires disposed inside the lower substrate BPL. The common voltage line PL may be formed of a single layer or multiple layers, and may overlap at least a portion of the common electrode CE. In FIGS. 3 and 4, the common voltage line PL is shown as having a shape similar to the contact terminals CT, but the embodiments are not limited thereto. The shape, position (or depth), and cross-sectional structure of the common voltage line PL may be variously changed according to embodiments. The first driving voltage may be supplied to the light emitting elements LE through the pixel circuits PXC, the contact terminals CT, and the pixel electrodes ET, and the second driving voltage may be supplied to the light emitting elements LE through the common voltage line PL.

Additionally, although FIGS. 3 and 4 illustrate only one insulating layer INS disposed on the pixel circuits PXC and surrounding the contact terminals CT, the embodiments are not limited thereto. For example, insulating layers and conductive layers may be disposed on the base substrate SB where the pixel circuits PXC are formed.

The contact terminals CT (or portions of the pixel circuits PXC) and the common voltage line PL may be exposed on the top surface of the lower substrate BPL. The contact terminals CT may be in contact with and/or electrically connected to the respective pixel electrodes ET at the exposed portions. The common voltage line PL may be in contact with and/or electrically connected to the common electrode CE at the exposed portion.

The contact terminals CT may electrically connect the pixel circuits PXC to the respective pixel electrodes ET. For example, the contact terminal CT electrically connected to the first pixel circuit PXC1 of the first pixel PX1 may be electrically connected to the first pixel electrode ET1 of the first pixel PX1, the contact terminal CT electrically connected to the second pixel circuit PXC2 of the first pixel PX1 may be electrically connected to the second pixel electrode ET2 of the first pixel PX1, and the contact terminal CT electrically connected to the third pixel circuit PXC3 of the first pixel PX1 may be electrically connected to the third pixel electrode ET3 of the first pixel PX1. The contact terminals CT may receive the first driving voltage from the respective pixel circuits PXC.

In an embodiment, the contact terminals CT may be electrically connected to the respective light emitting elements LE through (or via) the respective pixel electrodes ET and the respective bonding electrodes BDE. For example, the contact terminal CT electrically connected to the first pixel circuit PXC1 of the first pixel PX1 may be electrically connected to the first light emitting element LE1 of the first pixel PX1 through the first pixel electrode ET1 and the first bonding electrode BDE1 of the first pixel PX1, the contact terminal CT electrically connected to the second pixel circuit PXC2 of the first pixel PX1 may be electrically connected to the second light emitting element LE2 of the first pixel PX1 through the second pixel electrode ET2 and the second bonding electrode BDE2 of the first pixel PX1, and the contact terminal CT electrically connected to the third pixel circuit PXC3 of the first pixel PX1 may be electrically connected to the third light emitting element LE3 of the first pixel PX1 through the third pixel electrode ET3 and the third bonding electrode BDE3 of the first pixel PX1.

Although FIGS. 3 and 4 illustrate the contact terminals CT and the pixel circuits PXC in separate configurations, the embodiments are not limited thereto. For example, the contact terminals CT may be portions of the respective pixel circuits PXC. In one example, the contact terminals CT may be exposed electrodes (or wires) protruding from the top surfaces of the respective pixel circuits PXC.

The contact terminals CT and the common voltage line PL may contain a conductive material. For example, the contact terminals CT and the common voltage line PL may include, but not limited to, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof.

The light emitting element layer LEL may include the light emitting elements LE, and electrodes and/or wires electrically connected to the light emitting elements LE. The light emitting element layer LEL may further include insulating layers disposed around the light emitting elements LE.

In an embodiment, the light emitting elements LE may include light emitting elements LE disposed sequentially on the lower substrate BPL along the third direction DR3 in each pixel region where each pixel PX is disposed. For example, the light emitting elements LE may include the first light emitting element LE1, the second light emitting element LE2, and the third light emitting element LE3 disposed in different layers on the lower substrate BPL in each pixel region and overlapping each other in plan view. Accordingly, the pixel PX may emit light of the first color, light of the second color, or light of the third color alone, or may emit light that is a mixture of at least two of light of the first color, light of the second color, or light of the third color. For example, the pixel PX may emit light of various colors.

In an embodiment, the first light emitting elements LE1 of the pixels PX may be disposed in the same layer and may be simultaneously formed in the same process. The first light emitting elements LE1 of the pixels PX may be the same type of light emitting elements (for example, red micro light emitting diodes) and may contain a same material. The second light emitting elements LE2 of the pixels PX may be disposed in the same layer and may be simultaneously formed in the same process. The second light emitting elements LE2 of the pixels PX may be the same type of light emitting elements (for example, green micro light emitting diodes) and may contain a same material. The third light emitting elements LE3 of the pixels PX may be disposed in the same layer and may be simultaneously formed in the same process. The third light emitting elements LE3 of the pixels PX may be the same type of light emitting elements (for example, blue micro light emitting diodes) and may contain a same material.

In an embodiment, the first light emitting element LE1, the second light emitting element LE2, and the third light emitting element LE3 may be sequentially stacked on the lower substrate BPL. However, the stacking order of the light emitting elements LE disposed in each pixel PX may be variously changed according to embodiments. Depending on the arrangement position or stacking order of the light emitting elements LE, the arrangement position or stacking order of the bonding electrodes BDE and the connection electrodes CNE connected to the respective light emitting elements LE may also vary.

The first light emitting elements LE1 may be disposed on the first bonding electrodes BDE1. The second light emitting elements LE2 may be disposed on the second bonding electrodes BDE2. The third light emitting elements LE3 may be disposed on the third bonding electrodes BDE3.

In an embodiment, a semiconductor thin film layer (a semiconductor epitaxial stack or epi-layers) for forming semiconductor layers (for example, a first semiconductor layer SEM1, a light emitting layer EML, and a second semiconductor layer SEM2) of the light emitting elements LE may be formed (for example, epitaxially grown) on a manufacturing substrate, and bonded onto the lower substrate BPL by each bonding layer containing a bonding material. Thereafter, the light emitting elements LE and the bonding electrodes BDE may be formed by etching the semiconductor thin film layer and the bonding layer on the lower substrate BPL. Each of first contact electrodes CTE1 and second contact electrodes CTE2 of the light emitting elements LE may be formed on the manufacturing substrate together with the semiconductor thin film layer and etched on the lower substrate BPL, or may be formed on the semiconductor layers of the light emitting elements LE etched on the lower substrate BPL.

However, the embodiments are not limited thereto. In one example, at least one of the first light emitting elements LE1, the second light emitting elements LE2, or the third light emitting elements LE3 may be etched into a shape corresponding to the individual light emitting elements LE on the manufacturing substrate on which the semiconductor thin film layer is grown (or a transfer substrate on which the semiconductor thin film layer is transferred), and bonded onto the lower substrate BPL.

In an embodiment, a first bonding process for forming and/or disposing the first light emitting elements LE1 on the lower substrate BPL, a second bonding process for forming and/or disposing the second light emitting elements LE2 on the lower substrate BPL, and a third bonding process for forming and/or disposing the third light emitting elements LE3 on the lower substrate BPL may be performed sequentially. Accordingly, the first light emitting elements LE1, the second light emitting elements LE2, and the third light emitting elements LE3 may be sequentially formed and/or disposed on the lower substrate BPL.

Each of the light emitting elements LE may include the first semiconductor layer SEM1, the light emitting layer EML (also referred to as “active layer”), and the second semiconductor layer SEM2 that are sequentially disposed on the bonding electrode BDE. However, the position or stacking order of the first semiconductor layer SEM1, the light emitting layer EML, and the second semiconductor layer SEM2 is not limited thereto. For example, the stacking order of the first semiconductor layer SEM1, the light emitting layer EML, and the second semiconductor layer SEM2 of the light emitting elements LE may vary depending on the arrangement direction (or arrangement order) of the semiconductor thin film layer for forming the light emitting elements LE, or the sequence of an etching process and a bonding process.

In an embodiment, each of the light emitting elements LE may further include at least one of the first contact electrode CTE1 disposed on one surface or a surface (for example, the bottom surface) of the first semiconductor layer SEM1 or the second contact electrode CTE2 disposed on one surface or a surface (for example, the top surface) of the second semiconductor layer SEM2. Although FIGS. 3 and 4 illustrate a configuration in which the first contact electrode CTE1 and the second contact electrode CTE2 are included in the light emitting element LE, the embodiments are not limited thereto. For example, the first contact electrode CTE1 and the second contact electrode CTE2 may be considered as separate elements from the light emitting element LE, and may be selectively disposed on at least one surface or a surface of the light emitting element LE.

The first contact electrode CTE1 may be disposed on each bonding electrode BDE. For example, the first contact electrode CTE1 included in the first light emitting element LE1 of the first pixel PX1 may be disposed on the first bonding electrode BDE1 of the first pixel PX1. The first contact electrode CTE1 included in the second light emitting element LE2 of each pixel PX may be disposed on the second bonding electrode BDE2 of the corresponding pixel PX, and the first contact electrode CTE1 included in the third light emitting element LE3 of each pixel PX may be disposed on the third bonding electrode BDE3 of the corresponding pixel PX. The first contact electrode CTE1 may protect the first semiconductor layer SEM1 and may smoothly connect the light emitting element LE to the bonding electrode BDE.

In an embodiment, the first contact electrode CTE1 may be entirely disposed on one surface or a surface of the first semiconductor layer SEM1. For example, the first contact electrode CTE1 may be entirely disposed on the bottom surface of the first semiconductor layer SEM1. Accordingly, the first semiconductor layer SEM1 may be stably protected. In an embodiment, the first contact electrode CTE1 may be disposed on only a portion of the first semiconductor layer SEM1, or may be omitted.

The first contact electrode CTE1 may include metal, metal oxide, or other conductive materials. In an embodiment, the first contact electrode CTE1 may contain a transparent conductive material (for example, a transparent conductive oxide such as indium tin oxide (ITO) or indium zinc oxide (IZO), or other transparent conductive materials).

The first semiconductor layer SEM1 may be disposed on the first contact electrode CTE1. The first semiconductor layer SEM1 may include any one of a p-type semiconductor layer and an n-type semiconductor layer. In describing the embodiment of FIGS. 3 and 4, a case in which the first semiconductor layer SEM1 may include a p-type semiconductor layer and the display device 10 has a common cathode structure is described by way of example. However, the embodiments are not limited thereto. For example, the first semiconductor layer SEM1 may include an n-type semiconductor layer and the display device 10 may be formed in a common anode structure.

The first semiconductor layer SEM1 may contain a semiconductor material such as GaN, InGaN, InAlGaN, AlGaN, or AlN, and may be a p-type semiconductor layer doped with a first conductivity type dopant (or p-type dopant) such as magnesium (Mg), zinc (Zn), calcium (Ca), strontium (Sr), or barium (Ba). In one example, the first semiconductor layer SEM1 may contain a GaN semiconductor material (for example, p-GaN) doped with a first conductivity type dopant. However, the material constituting the first semiconductor layer SEM1 is not limited thereto, and the first semiconductor layer SEM1 may be composed of various other materials.

The light emitting layer EML may be disposed between the first semiconductor layer SEM1 and the second semiconductor layer SEM2. The light emitting layer EML may emit light by recombination of electron-hole pairs generated in response to an electrical signal applied through the first semiconductor layer SEM1 and the second semiconductor layer SEM2.

The light emitting layer EML may have any one of a single well structure, a multi-well structure, a single quantum well structure, a multi-quantum well (MQW) structure, a quantum dot structure, and a quantum wire structure, but the embodiments are not limited thereto. The light emitting layer EML may contain AlGaN, InGaN, or GaN, and various other materials may constitute the light emitting layer EML.

In embodiments, the light emitting layers EML of the light emitting elements LE disposed in different layers may emit light of different wavelength bands. For example, the first light emitting element LE1, the second light emitting element LE2, and the third light emitting element LE3 may each include the light emitting layer EML that emits light in different wavelength bands.

In an embodiment, the light emitting layer EML of the first light emitting element LE1 may emit light (for example, red light with a peak wavelength in the range of about 610 nm to about 650 nm) in a wavelength band corresponding to light of the first color, the light emitting layer EML of the second light emitting element LE2 may emit light (for example, green light with a peak wavelength in the range of about 510 nm to about 550 nm) in a wavelength band corresponding to light of the second color, and the light emitting layer EML of the third light emitting element LE3 may emit light (for example, blue light with a peak wavelength in the range of about 440 nm to about 480 nm) in a wavelength band corresponding to light of the third color. The light emitting layer EML of each of the light emitting elements LE may emit light of a different color or a different wavelength band other than the above-described colors or wavelength bands.

In an embodiment, the light emitting layer EML may have a multiple quantum well structure including a quantum well layer including InGaN and a barrier layer including GaN, AlGaN, or GaAIN, but is not limited thereto. In an embodiment, in case that the light emitting layer EML contains InGaN, the color or wavelength of light emitted from the light emitting layer EML may be adjusted by controlling the composition (or content) of indium (In). In describing embodiments, the term “composition” may also encompass the meaning of “content”.

For example, the composition of indium (In) (for example, the composition of indium (In) in the quantum well layer containing InGaN) contained in the light emitting layers EML of the first light emitting element LE1, the second light emitting element LE2, and the third light emitting element LE3 may differ from each other. In one example, the light emitting layer EML of the first light emitting element LE1 that emits red light may contain indium (In) at a higher composition than the light emitting layer EML of the second light emitting element LE2 that emits green light and the light emitting layer EML of the third light emitting element LE3 that emits blue light. Additionally, the light emitting layer EML of the third light emitting element LE3 may contain indium (In) at a lower composition than the light emitting layer EML of the first light emitting element LE1 and the light emitting layer EML of the second light emitting element LE2.

The second semiconductor layer SEM2 may be disposed on the light emitting layer EML. The second semiconductor layer SEM2 may include the other of a p-type semiconductor layer and an n-type semiconductor layer. In an embodiment, in case that the first semiconductor layer SEM1 may include a p-type semiconductor layer, the second semiconductor layer SEM2 may include an n-type semiconductor layer.

The second semiconductor layer SEM2 may contain a semiconductor material such as GaN, InGaN, InAlGaN, AlGaN, or AlN, and may be an n-type semiconductor layer doped with a second conductivity type dopant (or n-type dopant) such as germanium (Ge), selenium (Se), teleium (Te), or tin (Sn). In one example, the second semiconductor layer SEM2 may contain a GaN semiconductor material (for example, n-GaN) doped with a second conductivity type dopant. However, the material constituting the second semiconductor layer SEM2 is not limited thereto, and the second semiconductor layer SEM2 may be composed of various other materials.

In an embodiment, the first semiconductor layer SEM1, the light emitting layer EML, and the second semiconductor layer SEM2 of each of the light emitting elements LE may be formed from the semiconductor thin film layer or epi-layer formed by epitaxial growth on a semiconductor substrate.

The second contact electrode CTE2 may be disposed on the second semiconductor layer SEM2. The second contact electrode CTE2 may protect the second semiconductor layer SEM2 and may smoothly connect the light emitting element LE to the common electrode CE.

In an embodiment, the second contact electrode CTE2 may be entirely disposed on one surface or a surface of the second semiconductor layer SEM2. For example, the second contact electrode CTE2 may be entirely disposed on the top surface of the second semiconductor layer SEM2. Accordingly, the second semiconductor layer SEM2 may be stably protected. In an embodiment, the second contact electrode CTE2 may be disposed on only a portion of the second semiconductor layer SEM2, or may be omitted.

The second contact electrode CTE2 may include metal, metal oxide, or other conductive materials. In an embodiment, the second contact electrode CTE2 may contain a transparent conductive material (for example, a transparent conductive oxide such as ITO or IZO, or other transparent conductive materials). Accordingly, light generated in the light emitting element LE may pass through the second contact electrode CTE2 and be emitted to the upper side of the light emitting element LE.

In an embodiment, the electrodes of the light emitting element layer LEL may include the pixel electrodes ET and the connection electrodes CNE electrically connected to both ends of the light emitting elements LE, the bonding electrodes BDE electrically connected between the light emitting elements LE and the pixel electrodes ET, and the common electrode CE electrically connected to one ends of the light emitting elements LE through the connection electrodes CNE. Although FIGS. 3 and 4 illustrate an embodiment in which the common electrode CE is connected to the light emitting elements LE through the connection electrodes CNE, the embodiments are not limited thereto. For example, the common electrode CE may be directly in contact with or connected to at least one light emitting element LE, or the common electrode CE and at least one connection electrode CNE may be integrated into a single electrode.

In an embodiment, the insulating layers of the light emitting element layer LEL may include a lower insulating layer BIL, a first insulating layer IL1, a first interlayer insulating layer INL1, a second insulating layer IL2, a second interlayer insulating layer INL2, a third insulating layer IL3, and an upper insulating layer UIL that are sequentially disposed on the lower substrate BPL. Each of the insulating layers of the light emitting element layer LEL may be constituted with a single layer or multiple layers including at least one insulating material. In an embodiment, each of the insulating layers of the light emitting element layer LEL may include an inorganic insulating layer containing an inorganic insulating material (for example, silicon oxide (SiOₓ), silicon nitride (SiNₓ), silicon oxynitride (SiOₓN_{y}), silicon oxycarbide (SiOₓC_{y}), aluminum oxide (AlₓO_{y}), aluminum nitride (AlNₓ), zirconium oxide (ZrOₓ), hafnium oxide (HfOₓ), titanium oxide (TiOₓ), or other inorganic insulating materials), but is not limited thereto.

The pixel electrodes ET and the common electrode CE may be disposed on the lower substrate BPL. The pixel electrodes ET and the common electrode CE may include a conductive material. For example, the pixel electrodes ET and the common electrode CE may include at least one of gold (Au), copper (Cu), tin (Sn), titanium (Ti), aluminum (Al), silver (Ag), or other metals.

The pixel electrodes ET may be disposed between the lower substrate BPL and the bonding electrodes BDE to connect the lower substrate BPL to the bonding electrodes BDE. For example, the pixel electrodes ET may be electrically connected between the contact terminals CT of the respective pixel circuits PXC and the bonding electrodes BDE corresponding to the respective pixel circuits PXC.

The pixel electrodes ET may penetrate at least one of the insulating layers of the light emitting element layer LEL to be electrically connected to the contact terminals CT of the lower substrate BPL. For example, the first pixel electrode ET1 of the first pixel PX1 may penetrate the lower insulating layer BIL to be electrically connected to the contact terminal CT that may be connected to the first pixel circuit PXC1 of the first pixel PX1. Further, the first pixel electrode ET1 of the first pixel PX1 may be electrically connected to the first bonding electrode BDE1 of the first pixel PX1 disposed on the lower insulating layer BIL, and may be electrically connected, through the first bonding electrode BDE1, to the first contact electrode CTE1 and/or the first semiconductor layer SEM1 of the first light emitting element LE1 disposed in the first pixel PX1. For example, the first pixel electrode ET1 of the first pixel PX1 may be electrically connected to the first semiconductor layer SEM1 of the first light emitting element LE1 through the first bonding electrode BDE1 and the first contact electrode CTE1 of the first light emitting element LE1. If the first light emitting element LE1 does not include the first contact electrode CTE1, the first pixel electrode ET1 of the first pixel PX1 may be electrically connected to the first semiconductor layer SEM1 of the first light emitting element LE1 through the first bonding electrode BDE1.

The second pixel electrode ET2 of the first pixel PX1 may penetrate the lower insulating layer BIL, the first insulating layer IL1, and the first interlayer insulating layer INL1 to be electrically connected to the contact terminal CT that is connected to the second pixel circuit PXC2 of the first pixel PX1. The second pixel electrode ET2 of the first pixel PX1 may be electrically connected to the second bonding electrode BDE2 of the first pixel PX1 disposed on the first interlayer insulating layer INL1, and may be electrically connected, through the second bonding electrode BDE2, to the first contact electrode CTE1 and/or the first semiconductor layer SEM1 of the second light emitting element LE2 disposed in the first pixel PX1. For example, the second pixel electrode ET2 of the first pixel PX1 may be electrically connected to the first semiconductor layer SEM1 of the second light emitting element LE2 through the second bonding electrode BDE2 and the first contact electrode CTE1 of the second light emitting element LE2. If the second light emitting element LE2 does not include the first contact electrode CTE1, the second pixel electrode ET2 of the first pixel PX1 may be electrically connected to the first semiconductor layer SEM1 of the second light emitting element LE2 through the second bonding electrode BDE2.

The third pixel electrode ET3 of the first pixel PX1 may penetrate the lower insulating layer BIL, the first insulating layer IL1, the first interlayer insulating layer INL1, the second insulating layer IL2, and the second interlayer insulating layer INL2 to be electrically connected to the contact terminal CT that is connected to the third pixel circuit PXC3 of the first pixel PX1. Further, the third pixel electrode ET3 of the first pixel PX1 may be electrically connected to the third bonding electrode BDE3 of the first pixel PX1 disposed on the second interlayer insulating layer INL2, and may be electrically connected, through the third bonding electrode BDE3, to the first contact electrode CTE1 and/or the first semiconductor layer SEM1 of the third light emitting element LE3 disposed in the first pixel PX1. For example, the third pixel electrode ET3 of the first pixel PX1 may be electrically connected to the first semiconductor layer SEM1 of the third light emitting element LE3 through the third bonding electrode BDE3 and the first contact electrode CTE1 of the third light emitting element LE3. If the third light emitting element LE3 does not include the first contact electrode CTE1, the third pixel electrode ET3 of the first pixel PX1 may be electrically connected to the first semiconductor layer SEM1 of the third light emitting element LE3 through the third bonding electrode BDE3.

In the manner described above, the pixel electrodes ET of the second pixel PX2 and other pixels PX may be electrically connected between the contact terminals CT of the respective pixel circuits PXC and the respective light emitting elements LE.

The common electrode CE may penetrate at least one of the insulating layers of the light emitting element layer LEL to be electrically connected between the common voltage line PL of the lower substrate BPL and the connection electrodes CNE. For example, the common electrode CE may penetrate the lower insulating layer BIL, the first insulating layer IL1, the first interlayer insulating layer INL1, the second insulating layer IL2, the second interlayer insulating layer INL2, and the third insulating layer IL3, and may be in contact with the connection electrodes CNE.

The common electrode CE may be electrically connected to the second contact electrodes CTE2 and/or the second semiconductor layers SEM2 of the light emitting elements LE through the connection electrodes CNE. For example, the common electrode CE may be electrically connected to the second semiconductor layers SEM2 of the light emitting elements LE through the connection electrodes CNE and the second contact electrodes CTE2 of the light emitting elements LE. However, the embodiments are not limited thereto. For example, the common electrode CE may be directly in contact with and/or connected to the second contact electrode CTE2 or the second semiconductor layer SEM2 of at least one light emitting element LE.

The bonding electrodes BDE may be disposed below the respective light emitting elements LE. The bonding electrodes BDE may be electrically connected to the first contact electrodes CTE1 (or the first semiconductor layers SEM1) of the respective light emitting elements LE. In an embodiment, the bonding electrodes BDE may include the first bonding electrodes BDE1, the second bonding electrodes BDE2, and the third bonding electrodes BDE3 that are sequentially disposed above the lower substrate BPL along the third direction DR3. For example, the first bonding electrodes BDE1 of the pixels PX may be disposed separately from each other on the lower insulating layer BIL. The second bonding electrodes BDE2 of the pixels PX may be disposed separately from each other on the first interlayer insulating layer INL1. In each pixel PX, the second bonding electrode BDE2 may be disposed above the first light emitting element LE1, and may overlap the first light emitting element LE1. For example, the second bonding electrode BDE2 may cover the top surface of the first light emitting element LE1. The third bonding electrodes BDE3 of the pixels PX may be disposed separately from each other on the second interlayer insulating layer INL2. In each pixel PX, the third bonding electrode BDE3 may be disposed above the second light emitting element LE2, and may overlap the second light emitting element LE2. For example, the third bonding electrode BDE3 may cover the top surface of the second light emitting element LE2. In an embodiment, the third bonding electrode BDE3 of each pixel PX may overlap the first bonding electrode BDE1, the first light emitting element LE1, the second bonding electrode BDE2, and the second light emitting element LE2 of the corresponding pixel PX. The arrangement order or stacking order of the first bonding electrodes BDE1, the second bonding electrodes BDE2, and the third bonding electrodes BDE3 may vary depending on embodiments.

The bonding electrodes BDE may contain a conductive material for stably disposing the light emitting elements LE on the lower substrate BPL. For example, each of the bonding electrodes BDE may contain a transparent conductive material or eutectic metal capable of a bonding process.

In an embodiment, the bonding electrodes BDE disposed at the lowermost part of the bonding electrodes BDE may include a bonding metal layer containing at least one metal suitable for a bonding process. In one example, the first bonding electrodes BDE1 may be opaque electrodes that include a bonding metal layer containing a gold (Au)-tin (Sn) alloy or other bonding metals.

In an embodiment, the bonding electrodes BDE disposed on at least one light emitting element LE may contain a transparent conductive material capable of a bonding process. For example, the second bonding electrodes BDE2 and the third bonding electrodes BDE3 may be transparent electrodes containing a transparent conductive oxide such as indium tin oxide (ITO), zinc oxide (ZnO), or indium zinc oxide (IZO), or other transparent conductive materials. In an embodiment, the second bonding electrodes BDE2 may be formed to transmit light emitted from the first light emitting elements LE1, and the third bonding electrodes BDE3 may be formed to transmit light emitted from the first light emitting elements LE1 and the second light emitting elements LE2.

The connection electrodes CNE may be disposed on top of the light emitting elements LE. Although FIGS. 3 and 4 illustrate an embodiment in which the connection electrodes CNE are disposed entirely on the respective light emitting elements LE, the embodiments are not limited thereto. For example, the connection electrodes CNE may be disposed locally on only portions of the respective light emitting elements LE.

The connection electrodes CNE may include first connection electrodes CNE1, second connection electrodes CNE2, and third connection electrodes CNE3. The first connection electrodes CNE1 may be disposed on the first light emitting elements LE1 and the first insulating layer IL1. The first connection electrodes CNE1 may electrically connect the first light emitting elements LE1 to the common electrode CE. The second connection electrodes CNE2 may be disposed on the second light emitting elements LE2 and the second insulating layer IL2. The second connection electrodes CNE2 may electrically connect the second light emitting elements LE2 to the common electrode CE. The third connection electrodes CNE3 may be disposed on the third light emitting elements LE3 and the third insulating layer IL3. The third connection electrodes CNE3 may electrically connect the third light emitting elements LE3 to the common electrode CE.

The connection electrodes CNE may contain metal, metal oxide, or other conductive materials. In an embodiment, the connection electrodes CNE may contain a transparent conductive material (for example, a transparent conductive oxide such as indium tin oxide (ITO) or indium zinc oxide (IZO), or other transparent conductive materials). Accordingly, light generated in the light emitting elements LE may pass through the connection electrodes CNE.

The lower insulating layer BIL may be disposed on the lower substrate BPL. The lower insulating layer BIL may include openings (for example, contact holes or via holes) that expose the contact terminals CT and the common voltage line PL of the lower substrate BPL. At least portions of the pixel electrodes ET and common electrodes CE may be disposed in the openings. For example, the lower insulating layer BIL may surround at least portions of the pixel electrodes ET and the common electrode CE.

The first insulating layer IL1 may be disposed on the lower insulating layer BIL. The first insulating layer IL1 may surround the first bonding electrodes BDE1 and the first light emitting elements LE1. The first insulating layer IL1 may surround at least portions of the pixel electrodes ET (for example, the second pixel electrodes ET2 and the third pixel electrodes ET3) and the common electrode CE.

The first interlayer insulating layer INL1 may be disposed on the first insulating layer IL1. The first interlayer insulating layer INL1 may be disposed between the first light emitting element LE1 and the second bonding electrode BDE2 of each pixel PX. The first interlayer insulating layer INL1 may cover the first connection electrodes CNE1. The first interlayer insulating layer INL1 may surround at least portions of the pixel electrodes ET and the common electrode CE.

The second insulating layer IL2 may be disposed on the first interlayer insulating layer INL1. The second insulating layer IL2 may surround the second bonding electrodes BDE2 and the second light emitting elements LE2. The second insulating layer IL2 may surround at least portions of the pixel electrodes ET (for example, the third pixel electrodes ET3) and the common electrode CE.

The second interlayer insulating layer INL2 may be disposed on the second insulating layer IL2. The second interlayer insulating layer INL2 may cover the second connection electrodes CNE2. The second interlayer insulating layer INL2 may surround at least portions of the pixel electrodes ET and the common electrode CE.

The third insulating layer IL3 may be disposed on the second interlayer insulating layer INL2. The third insulating layer IL3 may surround the third bonding electrodes BDE3 and the third light emitting elements LE3. The third insulating layer IL3 may surround at least a portion of the common electrode CE.

The upper insulating layer UIL may be disposed on the third insulating layer IL3. The upper insulating layer UIL may be an insulating layer disposed at the uppermost part of the light emitting element layer LEL and may cover the light emitting elements LE, electrodes, and/or wires disposed in the light emitting element layer LEL. For example, the upper insulating layer UIL may cover the third connection electrodes CNE3 and the common electrode CE.

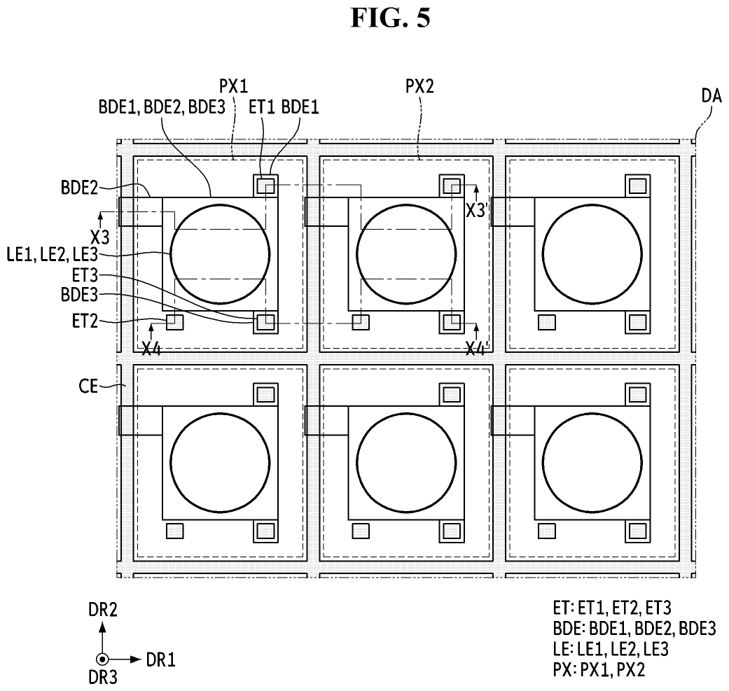

FIG. 5 is a schematic plan view illustrating a display area of a display device according to an embodiment. For example, FIG. 5 schematically shows a portion of the display area DA shown in FIG. 1, illustrating the display area DA according to an embodiment that may be different from the embodiment of FIG. 2.

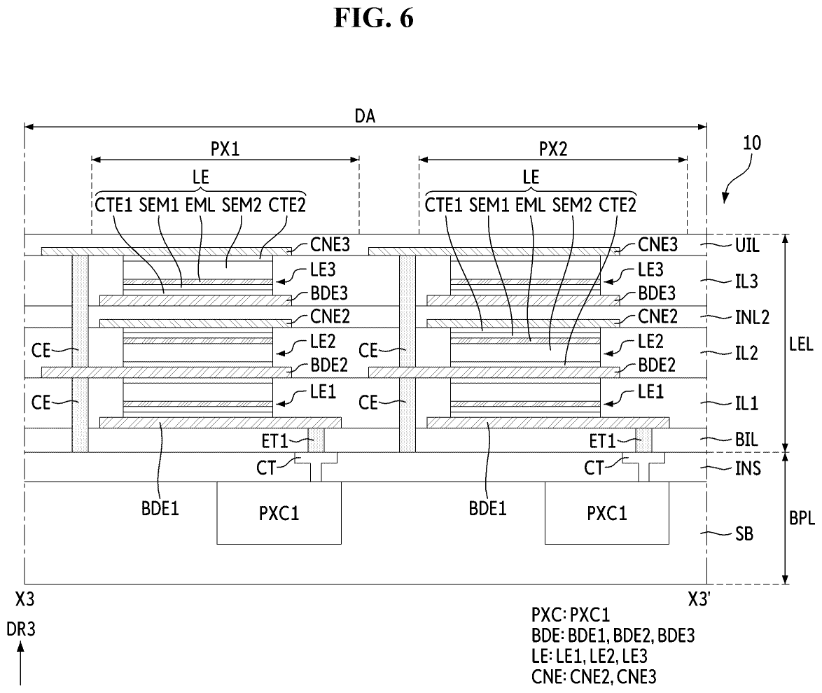

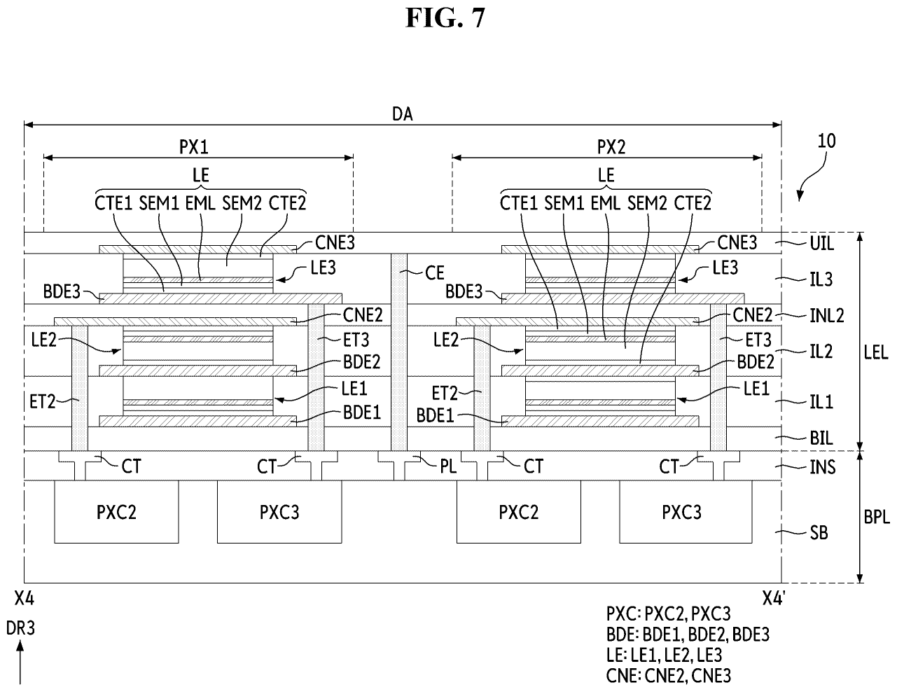

FIG. 6 is a schematic cross-sectional view showing a display device according to an embodiment. FIG. 7 is a schematic cross-sectional view showing a display device according to an embodiment. For example, FIG. 6 shows an embodiment of a cross section for a portion of the display area DA corresponding to line X3-X3′ in FIG. 5, and FIG. 7 shows an embodiment of a cross section for a portion of the display area DA corresponding to line X4-X4′ in FIG. 5. In describing the following embodiments, components substantially identical or similar to those of at least an embodiment described above are designated with the same reference numerals, and redundant descriptions will be omitted.

Referring to FIGS. 5 to 7 further to FIGS. 1 to 4, at least two of the light emitting elements LE of each pixel PX may share one bonding electrode BDE, and the bonding electrode BDE may be connected to the common electrode CE. Further, at least one pixel electrode ET may be connected to each light emitting element LE through a separate connection electrode CNE without passing through the bonding electrode BDE, or may be directly in contact with and/or connected to each light emitting element LE.

In an embodiment, the first light emitting element LE1 and the second light emitting element LE2 of each pixel PX may be connected in common to the second bonding electrode BDE2, and may share the second bonding electrode BDE2. The first light emitting element LE1 and the second light emitting element LE2 of each pixel PX may be electrically connected to the common electrode CE through the second bonding electrode BDE2. For example, the second bonding electrode BDE2 may protrude to overlap the common electrode CE in a region where the common electrode CE is disposed. In a region where the second bonding electrode BDE2 and the common electrode CE overlap, the second bonding electrode BDE2 and the common electrode CE may be electrically connected to each other.

In an embodiment, the arrangement directions of the first light emitting element LE1 and the second light emitting element LE2 may be opposite. For example, the first contact electrode CTE1, the first semiconductor layer SEM1, the light emitting layer EML, the second semiconductor layer SEM2, and the second contact electrode CTE2 of the first light emitting element LE1 may be sequentially disposed on the first bonding electrode BDE1. The first contact electrode CTE1 (or the first semiconductor layer SEM1) of the first light emitting element LE1 may be electrically connected to the first bonding electrode BDE1, and the second contact electrode CTE2 (or the second semiconductor layer SEM2) of the first light emitting element LE1 may be electrically connected to the second bonding electrode BDE2. The first contact electrode CTE1 (or the first semiconductor layer SEM1) of the first light emitting element LE1 may be electrically connected to the first pixel electrode ET1 through the first bonding electrode BDE1, and the second contact electrode CTE2 (or the second semiconductor layer SEM2) of the first light emitting element LE1 may be electrically connected to the common electrode CE through the second bonding electrode BDE2.

Conversely, the second contact electrode CTE2, the second semiconductor layer SEM2, the light emitting layer EML, the first semiconductor layer SEM1, and the first contact electrode CTE1 of the second light emitting element LE2 may be sequentially disposed on the second bonding electrode BDE2. The second contact electrode CTE2 (or the second semiconductor layer SEM2) of the second light emitting element LE2 may be electrically connected to the second bonding electrode BDE2, and the first contact electrode CTE1 (or the first semiconductor layer SEM1) of the second light emitting element LE2 may be electrically connected to the second connection electrode CNE2. The second contact electrode CTE2 (or the second semiconductor layer SEM2) of the second light emitting element LE2 may be electrically connected to the common electrode CE through the second bonding electrode BDE2, and the first contact electrode CTE1 (or the first semiconductor layer SEM1) of the second light emitting element LE2 may be electrically connected to the second pixel electrode ET2 through the second connection electrode CNE2.

In an embodiment, the first light emitting element LE1 and the second light emitting element LE2 may be in contact with both surfaces of the second bonding electrode BDE2. For example, the second bonding electrode BDE2 may be disposed directly on the first light emitting element LE1, and the second light emitting element LE2 may be disposed directly on the second bonding electrode BDE2. The first connection electrodes CNE1 and the first interlayer insulating layer INL1 of FIGS. 3 and 4 may be omitted.

Unlike the embodiment of FIGS. 3 and 4, in the embodiment of FIGS. 6 and 7, the second pixel electrode ET2 of each pixel PX may be electrically connected to the second connection electrode CNE2. The second pixel electrode ET2 may be electrically connected to the first contact electrode CTE1 (or the first semiconductor layer SEM1) of the second light emitting element LE2 through the second connection electrode CNE2. In an embodiment, the display device 10 may not include the second connection electrode CNE2, and the second pixel electrode ET2 of each pixel PX may be directly connected to the first contact electrode CTE1 or the first semiconductor layer SEM1 of the second light emitting element LE2.

According to the embodiment of FIGS. 5 to 7, at least two light emitting elements LE (for example, the first light emitting element LE1 and the second light emitting element LE2 of each pixel PX) may share one electrode (for example, the second bonding electrode BDE2), thereby simplifying or streamlining the structure and manufacturing process of the light emitting element layer LEL. For example, according to the embodiment of FIGS. 5 to 7, the number of electrodes disposed in the light emitting element layer LEL, conductive layers including the electrodes, and insulating layers covering the conductive layers may be reduced.

Additionally, FIGS. 3 and 4 and FIGS. 6 and 7 illustrate embodiments in which the third connection electrodes CNE3 are disposed on the third light emitting elements LE3, and the third light emitting elements LE3 are connected to the common electrode CE through the third connection electrodes CNE3, but the embodiments are not limited thereto. For example, in an embodiment, the common electrode CE may be in direct contact with the second contact electrodes CTE2 (or the second semiconductor layers SEM2) of the third light emitting elements LE3, and the third connection electrodes CNE3 may not be formed. The number of electrodes disposed in the light emitting element layer LEL may be further reduced. In one example, in the embodiment of FIGS. 6 and 7, in case that the common electrode CE is directly in contact with or connected to the third light emitting element LE3 without disposing the third connection electrode CNE3 in each pixel PX, each pixel PX may include three bonding electrodes BDE (for example, the first bonding electrode BDE1, the second bonding electrode BDE2, and the third bonding electrode BDE3) for appropriately disposing or bonding the first light emitting element LE1, the second light emitting element LE2, and the third light emitting element LE3 on the lower substrate BPL, and one connection electrode CNE (for example, the second connection electrode CNE2 disposed between the second light emitting element LE2 and the third light emitting element LE3).

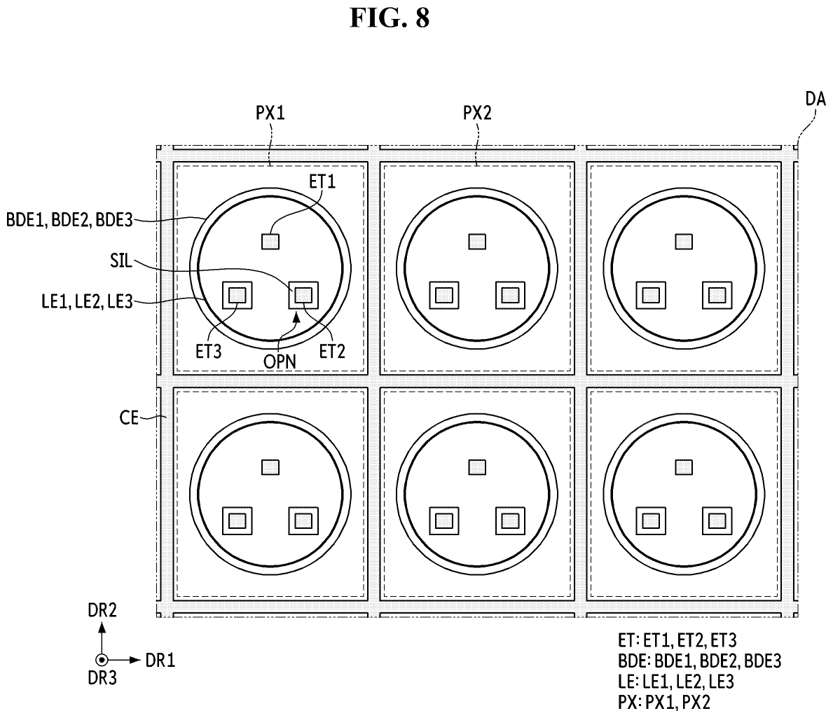

FIG. 8 is a schematic plan view illustrating a display area of a display device according to an embodiment. For example, FIG. 8 schematically shows a portion of the display area DA shown in FIG. 1, illustrating the display area DA according to an embodiment that may be different from the embodiment of FIG. 2.

Referring to FIG. 8 further to FIGS. 1 to 7, the pixel electrodes ET (or portions of the pixel electrodes ET) may be disposed in a region where the light emitting elements LE are disposed. Further, the pixel electrodes ET may overlap at least one bonding electrode BDE and/or at least one light emitting element LE. The position or arrangement order of the pixel electrodes ET may vary depending on embodiments.

In an embodiment, at least one (for example, the first bonding electrode BDE1 and the second bonding electrode BDE2, excluding the third bonding electrode BDE3 disposed at the uppermost part) of the bonding electrodes BDE may include an opening OPN formed in a region where the pixel electrodes ET, other than the pixel electrode ET electrically connected to the at least one bonding electrode BDE, are disposed, so as to be insulated from the other pixel electrodes ET. In one example, the first bonding electrode BDE1 may be opened to include the openings OPN having a size larger than the second pixel electrode ET2 and the third pixel electrode ET3, in regions where the second pixel electrode ET2 and the third pixel electrode ET3 are disposed. The first bonding electrode BDE1 may not be opened in a region where the first pixel electrode ET1 is disposed, and may be electrically connected to the first pixel electrode ET1. The second bonding electrode BDE2 may be opened to include the opening OPN having a size larger than the third pixel electrode ET3, in a region where the third pixel electrode ET3 is disposed. The second bonding electrode BDE2 may not be opened in a region where the second pixel electrode ET2 is disposed, and may be electrically connected to the second pixel electrode ET2. An insulating film SIL that surrounds each pixel electrode ET may be disposed on the sidewall of each of the openings OPN. Accordingly, even if the second pixel electrode ET2 penetrates the first bonding electrode BDE1, the second pixel electrode ET2 may be properly insulated from the first bonding electrode BDE1. Additionally, even if the third pixel electrode ET3 penetrates the first bonding electrode BDE1 and the second bonding electrode BDE2, the third pixel electrode ET3 may be properly insulated from the first bonding electrode BDE1 and the second bonding electrode BDE2.

Similarly, at least one (for example, the first light emitting element LE1 and the second light emitting element LE2, excluding the third light emitting element LE3 disposed at the uppermost part) of the light emitting elements LE may include the opening OPN formed in a region where the pixel electrodes ET, other than the pixel electrode ET electrically connected to the at least one light emitting element LE, are disposed, so as to be insulated from the other pixel electrodes ET. In one example, the first light emitting element LE1 may be opened to include the openings OPN having a size larger than the second pixel electrode ET2 and the third pixel electrode ET3, in regions where the second pixel electrode ET2 and the third pixel electrode ET3 are disposed. The second light emitting element LE2 may be opened to include the opening OPN having a size larger than the third pixel electrode ET3, in a region where the third pixel electrode ET3 is disposed. The second pixel electrode ET2 and the third pixel electrode ET3 may be surrounded by the insulating film SIL in their respective openings OPN.

In the manner described above, it is possible to dispose the pixel electrodes ET in a region where the light emitting elements LE are disposed and to properly connect the pixel electrodes ET to the respective bonding electrodes BDE and the respective light emitting elements LE, while preventing short-circuit defects between the pixel electrodes ET and other bonding electrodes BDE and/or other light emitting elements LE. As in the embodiment of FIG. 8, by disposing the pixel electrodes ET, the bonding electrodes BDE, and the light emitting elements LE in an overlapping manner, a pixel region where each pixel PX is disposed may be utilized more efficiently. In one example, the bonding electrodes BDE and/or the light emitting elements LE having a larger size (for example, a larger area) may be disposed in each pixel region.

In an embodiment, the light emitting elements LE and the bonding electrodes BDE may have corresponding planar shapes. For example, the light emitting elements LE and the bonding electrodes BDE may have substantially the same planar shape (for example, a circular planar shape). However, the embodiments are not limited thereto. For example, as in the embodiment of FIG. 2, the light emitting elements LE and the bonding electrodes BDE may have different planar shapes.

In an embodiment, the light emitting elements LE and the bonding electrodes BDE may have different sizes in plan view. For example, the bonding electrodes BDE may have a size larger than the light emitting elements LE in plan view. However, the embodiments are not limited thereto. For example, the light emitting elements LE and the bonding electrodes BDE may have the same size in plan view. In one example, the light emitting elements LE and the bonding electrodes BDE may be formed to have substantially the same planar shape and/or size by etching the light emitting elements LE and the bonding electrodes BDE substantially simultaneously or consecutively by a single mask process that uses the same mask.

FIG. 8 illustrates a modified embodiment of the embodiment of FIGS. 2 to 4, but the embodiments are not limited thereto. For example, even in the display device 10 having the electrode structure according to the embodiment of FIGS. 5 to 7, the pixel electrode ET may penetrate at least one bonding electrode BDE and/or light emitting element LE to be connected another bonding electrode BDE and/or another light emitting element LE in the same manner as in the embodiment of FIG. 8. Additionally, each embodiment may be applied alone or implemented in combination with at least one other embodiment, and all possible combinations of the embodiments are to be considered as being within the scope of the disclosure.

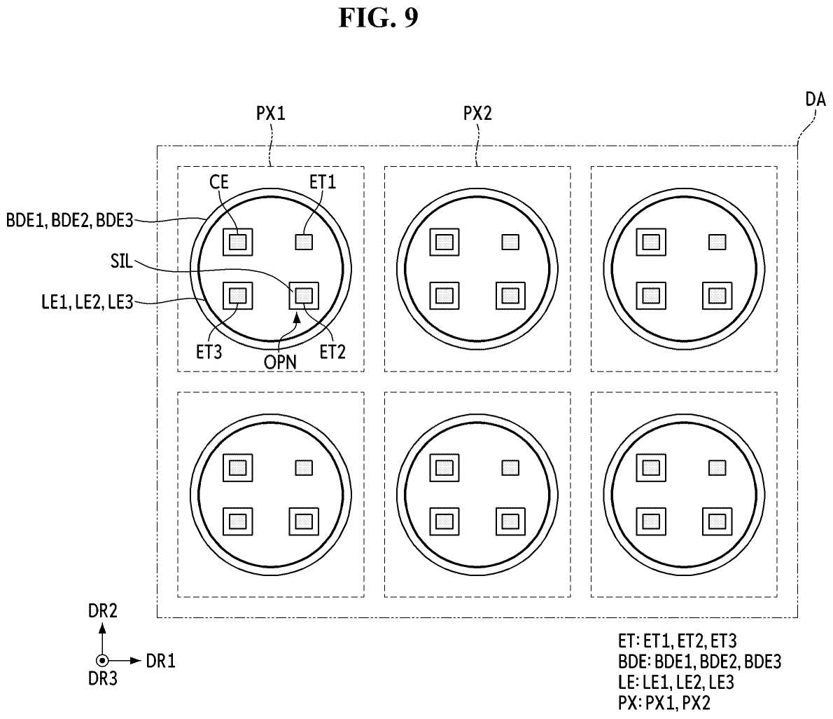

FIG. 9 is a schematic plan view illustrating a display area of a display device according to an embodiment. For example, FIG. 9 schematically shows a portion of the display area DA shown in FIG. 1, illustrating the display area DA according to an embodiment that may be different from the embodiment of FIG. 8.

Referring to FIG. 9 further to FIGS. 1 to 8, the display device 10 may include the common electrodes CE individually disposed in each pixel PX (or in each pixel group including at least two pixels PX). The common electrodes CE may be electrically connected to each other through the common voltage line PL or the like of the lower substrate BPL.

In an embodiment, the common electrodes CE may be disposed in a region where the light emitting elements LE are disposed. For example, the common electrodes CE may penetrate at least one bonding electrode BDE and/or the at least one light emitting element LE to be electrically connected to the light emitting elements LE of each pixel PX. In a portion where insulation between each common electrode CE and the bonding electrode BDE and/or the light emitting element LE disposed below the bonding electrode BDE needs to be ensured, the opening OPN may be formed in the bonding electrode BDE and/or the light emitting element LE, and the common electrode CE may be surrounded by the insulating film SIL in the opening OPN.

However, the embodiments are not limited thereto. For example, the common electrodes CE may be individually disposed in each pixel PX or each pixel group, but may not overlap the light emitting elements LE.

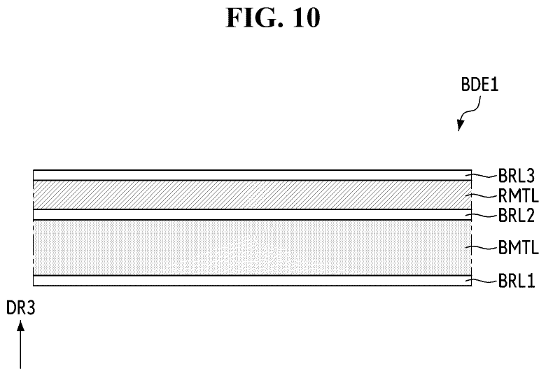

FIG. 10 is a schematic cross-sectional view showing a bonding electrode according to an embodiment. For example, FIG. 10 illustrates an embodiment of the structure and material of the first bonding electrode BDE1 disposed at the lowermost part of the bonding electrodes BDE in the light emitting element layer LEL.

Referring to FIG. 10, the first bonding electrode BDE1 may include a bonding metal layer BMTL. The first bonding electrode BDE1 may be opaque, but is not limited thereto.

In an embodiment, the first bonding electrode BDE1 may be formed of multiple layers including the bonding metal layer BMTL and a barrier layer (or a capping layer) disposed on at least one surface or a surface of the bonding metal layer BMTL. In one example, the first bonding electrode BDE1 may include the bonding metal layer BMTL, and a first barrier layer BRL1 and a second barrier layer BRL2 disposed on both surfaces of the bonding metal layer BMTL.

In an embodiment, the first bonding electrode BDE1 may further include a reflective layer RMTL disposed above the bonding metal layer BMTL. For example, the reflective layer RMTL may be disposed on the second barrier layer BRL2. In an embodiment, the first bonding electrode BDE1 may further include a third barrier layer BRL3 disposed on the reflective layer RMTL.

The bonding metal layer BMTL may contain a conductive material, for example, a bonding metal, suitable for bonding. For example, the bonding metal layer BMTL may contain a metal or a metal alloy with excellent electrical and thermal conductivity.

In an embodiment, the bonding metal layer BMTL may have a thickness sufficient to properly or readily perform a bonding process. For example, the bonding metal layer BMTL may have the largest thickness among the layers constituting the bonding electrode BDE. In one example, the bonding metal layer BMTL may have a thickness of about several hundred nanometers (nm), but is not limited thereto.

In an embodiment, the bonding metal layer BMTL may contain a gold (Au)-tin (Sn) alloy. A gold (Au)-tin (Sn) alloy has excellent adhesion and a low melting point, which enables the first light emitting elements LE1 (or the semiconductor thin film layer to be etched into the semiconductor layers of the first light emitting elements LE1) to be properly bonded onto the lower substrate BPL while reducing the temperature of a bonding process (for example, a wafer-to-wafer bonding process utilizing the bonding metal layer BMTL). Accordingly, it is possible to prevent the first light emitting elements LE1 or the peripheral elements from being damaged or deteriorated by the bonding process. Additionally, a gold (Au)-tin (Sn) alloy has low resistance variation with temperature and electrically stable characteristics. Therefore, the first pixel electrode ET1 and the first light emitting element LE1 may be electrically and/or physically stably connected by the bonding metal layer BMTL containing a gold (Au)-tin (Sn) alloy, and the reliability and operation characteristics of the first light emitting element LE1 and the pixel PX including it may be improved. However, the material of the bonding metal layer BMTL is not limited to a gold (Au)-tin (Sn) alloy. For example, the bonding metal layer BMTL may contain a metal or alloy, for example, titanium (Ti), with a low risk of foreign material generation caused by an etching process or the like, or may contain other highly reliable bonding metals such as zirconium (Zr), nickel (Ni), or chromium (Cr).

The first barrier layer BRL1 may be disposed below the bonding metal layer BMTL. For example, the first barrier layer BRL1 may be disposed between the first pixel electrode ET1 and the bonding metal layer BMTL, and may cover the bottom surface of the bonding metal layer BMTL.

The second barrier layer BRL2 may be disposed on top of the bonding metal layer BMTL. For example, the second barrier layer BRL2 may be disposed between the bonding metal layer BMTL and the reflective layer RMTL, and may cover the top surface of the bonding metal layer BMTL and the bottom surface of the reflective layer RMTL.

Each of the first barrier layer BRL1 and the second barrier layer BRL2 may contain a material suitable for preventing diffusion (for example, intermetallic diffusion), and may contain the same or different materials. Each of the first barrier layer BRL1 and the second barrier layer BRL2 may be formed of a material and/or thickness capable of ensuring conductivity of the first bonding electrode BDE1. In an embodiment, each of the first barrier layer BRL1 and the second barrier layer BRL2 may contain a material that is highly effective in preventing intermetallic diffusion, for example, titanium (Ti), titanium nitride (TiN), nickel (Ni), or other diffusion barrier materials, and may be formed to have a thickness less than or equal to the thickness of the reflective layer RMTL and/or the bonding metal layer BMTL. For example, each of the first barrier layer BRL1 and the second barrier layer BRL2 may be formed as a thin film containing a material suitable for preventing diffusion of a metal contained in the bonding metal layer BMTL and/or reflective layer RMTL.

The reflective layer RMTL may be disposed above the bonding metal layer BMTL. The bottom and top surfaces of the reflective layer RMTL may be covered with the second barrier layer BRL2 and the third barrier layer BRL3, respectively.

The reflective layer RMTL may contain a conductive material (for example, a metal) having high light reflectance. For example, the reflective layer RMTL may contain aluminum (Al), or other metals (for example, molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr)) having high light reflectance.

In an embodiment, the reflective layer RMTL may completely cover the bottom surfaces of the light emitting elements LE (for example, the first light emitting element LE1). For example, in plan view, the reflective layer RMTL of the first bonding electrode BDE1 disposed in each pixel PX may have a size larger than the first light emitting element LE1 disposed in the corresponding pixel PX, and may overlap the first light emitting element LE1 and the periphery of the first light emitting element LE1. By completely covering the bottom surface of the first light emitting element LE1, the reflective layer RMTL may effectively reflect light traveling in a downward direction from the first light emitting element LE1. Accordingly, the light efficiency of the pixel PX may be increased.

The third barrier layer BRL3 may be disposed on top of the reflective layer RMTL. For example, the third barrier layer BRL3 may be disposed between the reflective layer RMTL and the first light emitting element LE1, and may cover the top surface of the reflective layer RMTL.

The third barrier layer BRL3 may contain a material suitable for preventing diffusion (for example, intermetallic diffusion) and may be formed of a material and/or thickness capable of ensuring conductivity of the first bonding electrode BDE1. In an embodiment, the third barrier layer BRL3 may contain titanium (Ti), titanium nitride (TiN), nickel (Ni), or other diffusion barrier materials. For example, the third barrier layer BRL3 may be formed as a thin film (for example, a thin film with a thickness of about 20 nm or less) containing titanium nitride (TiN). Accordingly, the conductivity of the first bonding electrode BDE1 may be ensured while preventing diffusion of a metal contained in the reflective layer RMTL.

In an embodiment, the first bonding electrode BDE1 may be formed from a first bonding layer used to bond the first light emitting elements LE1 or the semiconductor thin film layer for forming the first light emitting elements LE1 onto the lower substrate BPL. For example, after bonding the first light emitting elements LE1 or the semiconductor thin film layer for forming the first light emitting elements LE1 onto the lower substrate BPL using the first bonding layer (for example, an opaque bonding layer containing a bonding metal) that may include the bonding metal layer BMTL, the reflective layer RMTL, and the first, second, and third barrier layers BRL1, BRL2, and BRL3, the first bonding layer may be etched to form the first bonding electrodes BDE1 of the pixels PX.

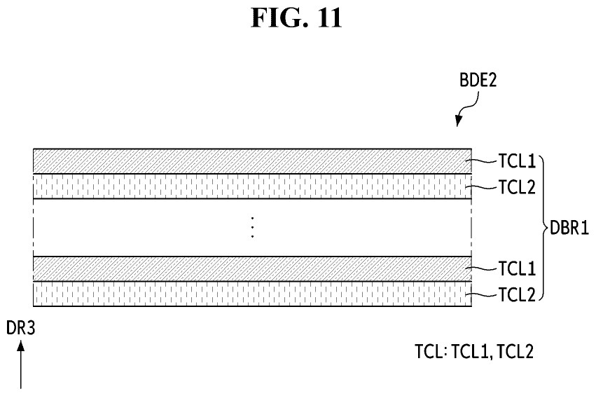

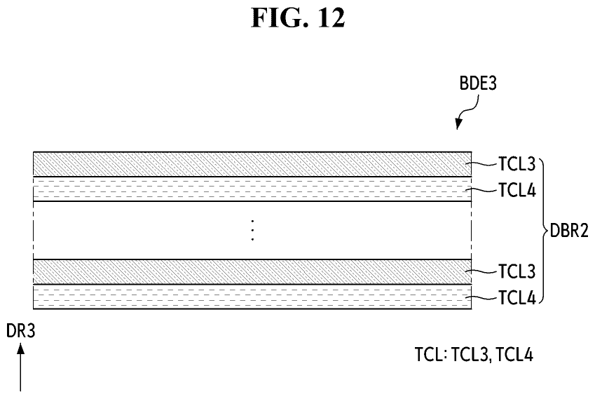

FIG. 11 is a schematic cross-sectional view showing a bonding electrode according to an embodiment. FIG. 12 is a schematic cross-sectional view showing a bonding electrode according to an embodiment. For example, FIGS. 11 and 12 illustrate respective embodiments of the structure and material of the second bonding electrode BDE2 and the third bonding electrode BDE3 that are disposed on at least one light emitting element LE among the bonding electrodes BDE in the light emitting element layer LEL.

Referring to FIGS. 11 and 12, each of the second bonding electrode BDE2 and the third bonding electrode BDE3 may include a distributed Bragg reflector (DBR) including transparent conductive layers TCL. For example, each of the second bonding electrode BDE2 and the third bonding electrode BDE3 may be formed of a multilayer distributed Bragg reflector that is transparent and conductive, or may further include additional layers or elements in addition to the distributed Bragg reflector.

The transparent conductive layers TCL of each of the second bonding electrode BDE2 and the third bonding electrode BDE3 may contain a transparent conductive material capable of a bonding process. In one example, the transparent conductive layers TCL of each of the second bonding electrode BDE2 and the third bonding electrode BDE3 may contain a transparent conductive material that can be melted and solidified by a bonding process performed at a temperature (for example, a temperature of about 500° C. or less) that does not damage the light emitting elements LE, thereby enabling stable attachment of the second light emitting elements LE2 and the third light emitting elements LE3 onto the lower substrate BPL. In an embodiment, the transparent conductive layers TCL of each of the second bonding electrode BDE2 and the third bonding electrode BDE3 may contain ITO, ZnO, IZO, or other transparent conductive oxides. Accordingly, each of the second bonding electrode BDE2 and the third bonding electrode BDE3 may be both transparent and conductive.

Further, the transparent conductive layers TCL of each of the second bonding electrode BDE2 and the third bonding electrode BDE3 may be formed as distributed Bragg reflectors that selectively reflect light in a given wavelength band. For example, the second bonding electrode BDE2 may have a material, structure, and/or thickness suitable for transmitting light of the first color emitted from the first light emitting element LE1 while reflecting light of the second color emitted from the second light emitting element LE2. The third bonding electrode BDE3 may have a material, structure, and/or thickness suitable for transmitting light of the first color and light of the second color emitted from the first light emitting element LE1 and the second light emitting element LE2 while reflecting light of the third color emitted from the third light emitting element LE3.

In an embodiment, as shown in FIG. 11, the second bonding electrode BDE2 may include a first distributed Bragg reflector DBR1 composed of at least one pair of a first transparent conductive layer TCL1 and a second transparent conductive layer TCL2, which are alternately (for example, repeatedly and/or periodically) disposed or stacked along the third direction DR3. In one example, the second bonding electrode BDE2 may include the first distributed Bragg reflector DBR1 of a multilayer including first transparent conductive layers TCL1 and the second transparent conductive layers TCL2 that are alternately stacked. The stacking order of the first transparent conductive layers TCL1 and the second transparent conductive layers TCL2 may vary depending on embodiments. For example, the first transparent conductive layer TCL1 or the second transparent conductive layer TCL2 may be disposed at the lowermost part of the second bonding electrode BDE2.

In an embodiment, the second bonding electrode BDE2 may be formed from a second bonding layer used for bonding the second light emitting elements LE2 or the semiconductor thin film layer for forming the second light emitting elements LE2 onto the lower substrate BPL. For example, after bonding the second light emitting elements LE2 or the semiconductor thin film layer for forming the second light emitting elements LE2 onto the lower substrate BPL using the second bonding layer (for example, a multilayer first transparent bonding layer containing a transparent conductive oxide and including the first distributed Bragg reflector DBR1) that may include at least one pair of the alternately stacked first transparent conductive layer TCL1 and second transparent conductive layer TCL2, the second bonding layer may be etched to form the second bonding electrodes BDE2 of the pixels PX.

The first transparent conductive layer TCL1 and the second transparent conductive layer TCL2 may have different refractive indices. For example, the first transparent conductive layer TCL1 may have a first refractive index, and the second transparent conductive layer TCL2 may have a second refractive index lower than the first refractive index.

In an embodiment, the first transparent conductive layer TCL1 and the second transparent conductive layer TCL2 may contain the same transparent conductive oxide, but the second transparent conductive layer TCL2 may have a higher concentration of pores compared to the first transparent conductive layer TCL1. For example, the first transparent conductive layer TCL1 and the second transparent conductive layer TCL2 may contain the same transparent conductive oxide at different densities and may have different refractive indices. In one example, the first transparent conductive layer TCL1 may be a high-density transparent conductive layer, and the second transparent conductive layer TCL2 may be a low-density transparent conductive layer, for example, a porous transparent conductive layer.

In an embodiment, the first transparent conductive layer TCL1 and the second transparent conductive layer TCL2 may contain ITO, ZnO, or IZO. For example, the first transparent conductive layer TCL1 may contain ITO (for example, dense ITO) and the second transparent conductive layer TCL2 may contain porous ITO. By way of example, the first transparent conductive layer TCL1 may contain ZnO (for example, dense ZnO) or IZO (for example, dense IZO), and the second transparent conductive layer TCL2 may contain porous ZnO or porous IZO.

In an embodiment, the first transparent conductive layer TCL1 and the second transparent conductive layer TCL2 may further contain another material (for example, gallium (Ga)) doped into the transparent conductive oxide. For example, each of the first transparent conductive layer TCL1 and the second transparent conductive layer TCL2 may be made of gallium (Ga)-doped ZnO or porous ZnO, or may contain gallium (Ga)-doped IZO or porous IZO. By doping with gallium (Ga), the conductivity of the second bonding electrode BDE2 may be increased.

In an embodiment, the first transparent conductive layer TCL1 and the second transparent conductive layer TCL2 may be formed by different film forming methods. For example, the first transparent conductive layer TCL1 may be formed by a sputtering method and the second transparent conductive layer TCL2 may be formed by a sol-gel method. The first transparent conductive layer TCL1 and the second transparent conductive layer TCL2 may also be formed by other film forming methods.

The first distributed Bragg reflector DBR1 may transmit light emitted from the first light emitting element LE1 and reflect light emitted from the second light emitting element LE2. For example, the first distributed Bragg reflector DBR1 may transmit light of the first color (for example, red) emitted from the first light emitting element LE1 and reflect light of the second color (for example, green) emitted from the second light emitting element LE2.

In an embodiment, the wavelength band and reflectance of light reflected by the first distributed Bragg reflector DBR1 may be controlled or optimized by adjusting at least one of the film quality (for example, the porosity of the second transparent conductive layer TCL2) of the first transparent conductive layer TCL1 and the second transparent conductive layer TCL2 that constitute the first distributed Bragg reflector DBR1, the number of pairs of the first transparent conductive layer TCL1 and the second transparent conductive layer TCL2, or the thickness of the first transparent conductive layer TCL1 and the second transparent conductive layer TCL2. For example, if it is desired to selectively reflect light of the second color emitted from the second light emitting element LE2 using the first distributed Bragg reflector DBR1, a wavelength band (for example, a peak wavelength band of green light emitted from the second light emitting element LE2) corresponding to the light of the second color emitted from the second light emitting element LE2 may be set as a target reflection wavelength of the first distributed Bragg reflector DBR1, and the film quality, number of pairs, and/or thickness of the first transparent conductive layer TCL1 and the second transparent conductive layer TCL2 may be adjusted or optimized according to the target reflection wavelength.

In an embodiment, as shown in FIG. 12, the third bonding electrode BDE3 may include a second distributed Bragg reflector DBR2 composed of at least one pair of a third transparent conductive layer TCL3 and a fourth transparent conductive layer TCL4, which are alternately disposed or stacked along the third direction DR3. In one example, the third bonding electrode BDE3 may include the second distributed Bragg reflector DBR2 of a multilayer including third transparent conductive layers TCL3 and fourth transparent conductive layers TCL4 that are alternately stacked. The stacking order of the third transparent conductive layers TCL3 and the fourth transparent conductive layers TCL4 may vary depending on embodiments. For example, the third transparent conductive layer TCL3 or the fourth transparent conductive layer TCL4 may be disposed at the lowermost part of the third bonding electrode BDE3.

In an embodiment, the third bonding electrode BDE3 may be formed from a third bonding layer used to bond the third light emitting elements LE3 or the semiconductor thin film layer for forming the third light emitting elements LE3 onto the lower substrate BPL. For example, after bonding the third light emitting elements LE3 or the semiconductor thin film layer for forming the third light emitting elements LE3 onto the lower substrate BPL using the third bonding layer (for example, a multilayer second transparent bonding layer containing a transparent conductive oxide and including the second distributed Bragg reflector DBR2) may include at least one pair of the alternately stacked third transparent conductive layer TCL3 and fourth transparent conductive layer TCL4, the third bonding layer may be etched to form the third bonding electrodes BDE3 of the pixels PX.

The third transparent conductive layer TCL3 and the fourth transparent conductive layer TCL4 may have different refractive indices. For example, the third transparent conductive layer TCL3 may have a third refractive index, and the fourth transparent conductive layer TCL4 may have a fourth refractive index lower than the third refractive index.

In an embodiment, the third transparent conductive layer TCL3 and the fourth transparent conductive layer TCL4 may contain the same transparent conductive oxide, but the fourth transparent conductive layer TCL4 may have a higher concentration of pores compared to the third transparent conductive layer TCL3. For example, the third transparent conductive layer TCL3 and the fourth transparent conductive layer TCL4 may contain the same transparent conductive oxide at different densities and may have different refractive indices. In one example, the third transparent conductive layer TCL3 may be a high-density transparent conductive layer, and the fourth transparent conductive layer TCL4 may be a low-density transparent conductive layer, for example, a porous transparent conductive layer.

In an embodiment, the third transparent conductive layer TCL3 and the fourth transparent conductive layer TCL4 may contain ITO, ZnO, or IZO. For example, the third transparent conductive layer TCL3 may contain ITO (for example, dense ITO) and the fourth transparent conductive layer TCL4 may contain porous ITO. By way of example, the third transparent conductive layer TCL3 may contain ZnO (for example, dense ZnO) or IZO (for example, dense IZO), and the fourth transparent conductive layer TCLA may contain porous ZnO or porous IZO.

In an embodiment, the third transparent conductive layer TCL3 and the fourth transparent conductive layer TCL4 may further contain another material (for example, gallium (Ga)) doped into the transparent conductive oxide. For example, each of the third transparent conductive layer TCL3 and the fourth transparent conductive layer TCL4 may be made of gallium (Ga)-doped ZnO or porous ZnO, or may contain gallium (Ga)-doped IZO or porous IZO. By doping with gallium (Ga), the conductivity of the third bonding electrode BDE3 may be increased.

In an embodiment, the first distributed Bragg reflector DBR1 and the second distributed Bragg reflector DBR2 may be formed using the same transparent conductive material. In one example, the first transparent conductive layer TCL1 and the third transparent conductive layer TCL3 may be formed as high-density transparent conductive layers containing the same transparent conductive oxide, and the second transparent conductive layer TCL2 and the fourth transparent conductive layer TCL4 may be formed as porous films containing the same transparent conductive oxide as in the first transparent conductive layer TCL1 and the third transparent conductive layer TCL3, but at a lower concentration.

In an embodiment, the third transparent conductive layer TCL3 and the fourth transparent conductive layer TCL4 may be formed by different film forming methods. For example, the third transparent conductive layer TCL3 may be formed by a sputtering method and the fourth transparent conductive layer TCL4 may be formed by a sol-gel method. The third transparent conductive layer TCL3 and the fourth transparent conductive layer TCL4 may also be formed by other film forming methods.

The second distributed Bragg reflector DBR2 may transmit light emitted from the first light emitting element LE1 and the second light emitting element LE2, and reflect light emitted from the third light emitting element LE3. For example, the second distributed Bragg reflector DBR2 may transmit light of the first color (for example, red) emitted from the first light emitting element LE1 and light of the second color (for example, green) emitted from the second light emitting element LE2, and reflect light of the third color (for example, blue) emitted from the third light emitting element LE3.

In an embodiment, the wavelength band and reflectance of light reflected by the second distributed Bragg reflector DBR2 may be controlled or optimized by adjusting at least one of the film quality (for example, the porosity of the fourth transparent conductive layer TCL4) of the third transparent conductive layer TCL3 and the fourth transparent conductive layer TCL4 that constitute the second distributed Bragg reflector DBR2, the number of pairs of the third transparent conductive layer TCL3 and the fourth transparent conductive layer TCL4, or the thickness of the third transparent conductive layer TCL3 and the fourth transparent conductive layer TCL4. For example, if it is desired to selectively reflect light of the third color emitted from the third light emitting element LE3 using the second distributed Bragg reflector DBR2, a wavelength band (for example, a peak wavelength band of blue light emitted from the third light emitting element LE3) corresponding to the light of the third color emitted from the third light emitting element LE3 may be set as a target reflection wavelength of the second distributed Bragg reflector DBR2, and the film quality, number of pairs, and/or thickness of the third transparent conductive layer TCL3 and the fourth transparent conductive layer TCL4 may be adjusted or optimized according to the target reflection wavelength.

In embodiments, the target reflection wavelength of the first distributed Bragg reflector DBR1 (or the second bonding electrode BDE2) may differ from the target reflection wavelength of the second distributed Bragg reflector DBR2 (or the third bonding electrode BDE3). Accordingly, at least one of the film quality, structure, number of pairs, or thickness of the first distributed Bragg reflector DBR1 and the second distributed Bragg reflector DBR2 may be different.

For example, at least one of the porosity of the second transparent conductive layer TCL2 and the porosity of the fourth transparent conductive layer TCL4, the number of pairs of the first transparent conductive layer TCL1 and the second transparent conductive layer TCL2 that constitute the first distributed Bragg reflector DBR1 and the number of pairs of the third transparent conductive layer TCL3 and the fourth transparent conductive layer TCL4 that constitute the second distributed Bragg reflector DBR2, or the pair thickness of the first transparent conductive layer TCL1 and the second transparent conductive layer TCL2 that constitute the first distributed Bragg reflector DBR1 and the pair thickness of the third transparent conductive layer TCL3 and the fourth transparent conductive layer TCL4 that constitute the second distributed Bragg reflector DBR2 may be different.

In one example, the second transparent conductive layer TCL2 and the fourth transparent conductive layer TCL4 may be formed as porous films containing the same transparent conductive oxide, but the porosity of the second transparent conductive layer TCL2 and the fourth transparent conductive layer TCL4 may be different. Accordingly, the characteristics (for example, reflection wavelength and/or reflectance) of the first distributed Bragg reflector DBR1 and the second distributed Bragg reflector DBR2 may be different.

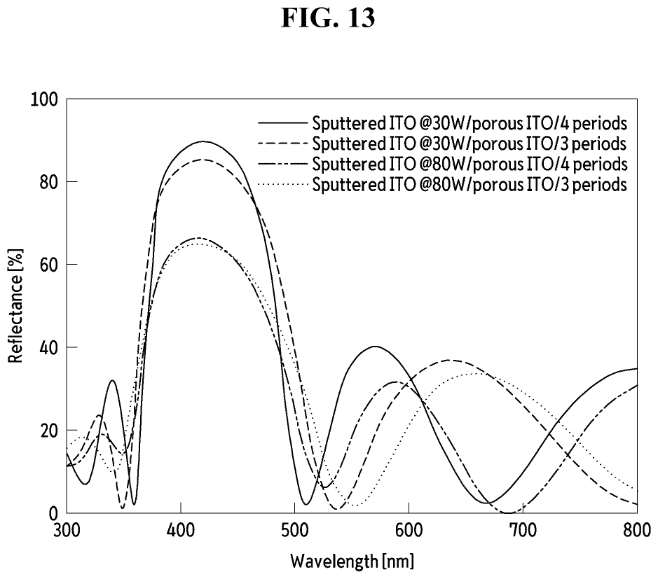

FIG. 13 is a graph illustrating the reflection characteristics of a distributed Bragg reflector based on the number of pairs and the film forming condition of transparent conductive layers. For example, FIG. 13 shows the wavelength-dependent reflectance based on the film forming condition and the number of pairs, for the distributed Bragg reflector (for example, the first distributed Bragg reflector DBR1 or the second distributed Bragg reflector DBR2) in which high-density transparent conductive layers (for example, the first transparent conductive layers TCL1 or the third transparent conductive layers TCL3) containing ITO and low-density transparent conductive layers (for example, the second transparent conductive layers TCL2 or the fourth transparent conductive layers TCL4) containing porous ITO are alternately stacked.

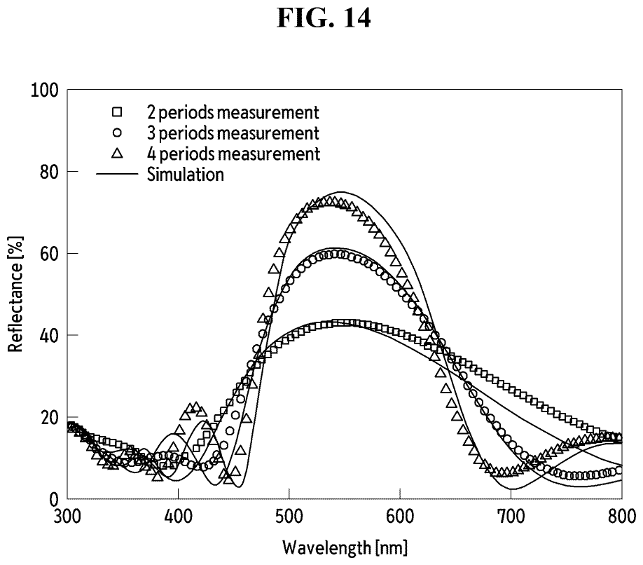

FIG. 14 is a graph illustrating the reflection characteristics of a distributed Bragg reflector based on the number of pairs of transparent conductive layers. For example, FIG. 14 shows the wavelength-dependent reflectance based on the number of pairs, for the distributed Bragg reflector in which high-density transparent conductive layers containing ITO and low-density transparent conductive layers containing porous ITO are alternately stacked.

Referring to FIGS. 13 and 14 further to FIGS. 1 to 12, the reflection wavelength and reflectance of the distributed Bragg reflector may vary depending on the film forming conditions of the transparent conductive layers TCL, the film quality of the transparent conductive layers TCL according to these conditions, and the number of pairs of high-density transparent conductive layers and low-density transparent conductive layers (for example, porous transparent conductive layers). For example, in case that the high-density transparent conductive layers are formed by setting the output of deposition equipment to 30 W and 80 W, respectively, the peak reflection wavelength and/or reflectance of the distributed Bragg reflector may vary depending on the output value of the deposition equipment. As an example of a film forming condition for controlling the film quality of the transparent conductive layers TCL, FIG. 13 discloses experimental results obtained by adjusting or changing the output of the deposition equipment used to perform a sputtering process, but the conditions or methods for controlling the film quality of the transparent conductive layers TCL are not limited thereto. For example, the film quality of the transparent conductive layers TCL may be controlled by changing deposition conditions other than the output of the deposition equipment. Additionally, by adjusting or changing the porosity of the low-density transparent conductive layers to adjust or change their refractive indices, the reflection characteristics of the distributed Bragg reflector may be adjusted or optimized to match the target reflection wavelength or reflectance.

The peak reflection wavelength and reflectance may also vary depending on the number of pairs of high-density and low-density transparent conductive layers. For example, as shown in FIG. 13, in case that the number of pairs (or periods) of high-density and low-density transparent conductive layers is three and four, the peak reflection wavelength and/or reflectance of the distributed Bragg reflector may vary. Additionally, as shown in FIG. 14, the reflectance of the distributed Bragg reflector may increase as the number of pairs of high-density and low-density transparent conductive layers increases from two to four. Furthermore, the peak reflection wavelength or the overall shape of the graph may vary depending on the number of pairs of high-density and low-density transparent conductive layers.

Moreover, the wavelength of light reflected by the distributed Bragg reflector may also vary depending on the thickness of the transparent conductive layers constituting the distributed Bragg reflector. Therefore, by adjusting or optimizing the thickness of the transparent conductive layers TCL constituting the distributed Bragg reflector to match the target reflection wavelength, light at the target reflection wavelength may be effectively reflected.

As in the aforementioned embodiments, the second bonding electrode BDE2, which covers the first light emitting element LE1 and is disposed below the second light emitting element LE2, may include the first distributed Bragg reflector DBR1 that is suitable or optimized for transmitting light of the first color emitted from the first light emitting element LE1 and reflecting light of the second color emitted from the second light emitting element LE2. Additionally, the third bonding electrode BDE3, which covers the first light emitting element LE1 and the second light emitting element LE2 and is disposed below the third light emitting element LE3, may include the second distributed Bragg reflector DBR2 that is suitable or optimized for transmitting light of the first color and light of the second color emitted from the first light emitting element LE1 and the second light emitting element LE2 and reflecting light of the third color emitted from the third light emitting element LE3.

Due to the difference in the target reflection wavelengths of the first distributed Bragg reflector DBR1 and the second distributed Bragg reflector DBR2, the first distributed Bragg reflector DBR1 (or the second bonding electrode BDE2) and the second distributed Bragg reflector DBR2 (or the third bonding electrode BDE3) may have different materials, film qualities, structures, and/or thicknesses. For example, at least one of the film quality (for example, the porosity (or refractive index) of the second transparent conductive layers TCL and the porosity (or refractive index) of the fourth transparent conductive layers TCL4), the number of pairs, or the thickness of the transparent conductive layers TCL constituting each of the first distributed Bragg reflector DBR1 and the second distributed Bragg reflector DBR2 may be different.

According to embodiments, it is possible to provide a highly reliable display device 10 having a stacked structure including the light emitting elements LE of different colors stacked sequentially on the lower substrate BPL. For example, as a bonding material for forming the second bonding electrodes BDE2 and the third bonding electrodes BDE3, a transparent conductive material (for example, a transparent conductive oxide), which is an inorganic material with physically and/or electrically stable characteristics even at high temperatures and possesses transparency and conductivity, may be used to stably bond the second light emitting elements LE2 and the third light emitting elements LE3 onto the first light emitting elements LE1. Accordingly, light emitted from each of the light emitting elements LE may pass through the bonding electrodes BDE above them and be appropriately emitted toward the top of the pixels PX. Further, the reliability (for example, conductivity and physical stability) of the second bonding electrodes BDE2 and the third bonding electrodes BDE3 may be secured and/or improved, and the second light emitting elements LE2 and the third light emitting elements LE3 may be stably attached onto the lower substrate BPL by the second bonding electrodes BDE2 and the third bonding electrodes BDE3. For example, the second light emitting elements LE2 and the third light emitting elements LE3 may be physically and/or electrically stably bonded to a lower layer including the lower substrate BPL by the second bonding electrodes BDE2 and the third bonding electrodes BDE3, respectively.

Furthermore, according to embodiments, light directed downwardly from the second light emitting elements LE2 may be reflected by the second bonding electrodes BDE2. Accordingly, light emitted from the second light emitting elements LE2 may be prevented from entering the first light emitting elements LE1 and causing the first light emitting elements LE1 to emit light in an unintended form. Similarly, light directed downwardly from the third light emitting elements LE3 may be reflected by the third bonding electrodes BDE3. Accordingly, light emitted from the third light emitting element LE3 may be prevented from entering the first light emitting elements LE1 and/or the second light emitting elements LE2 and causing the first light emitting elements LE1 and/or the second light emitting elements LE2 to emit light in an unintended form.

Thus, according to embodiments, the first light emitting elements LE1, the second light emitting elements LE2, and the third light emitting elements LE3 may be driven to appropriately emit light at a targeted luminance in response to the respective driving signals. Additionally, it is possible to prevent color mixing caused by unintended mixing of light emitted from the first light emitting elements LE1, the second light emitting elements LE2, and the third light emitting elements LE3 and improve the optical characteristics (for example, color coordinates) of the pixels PX.

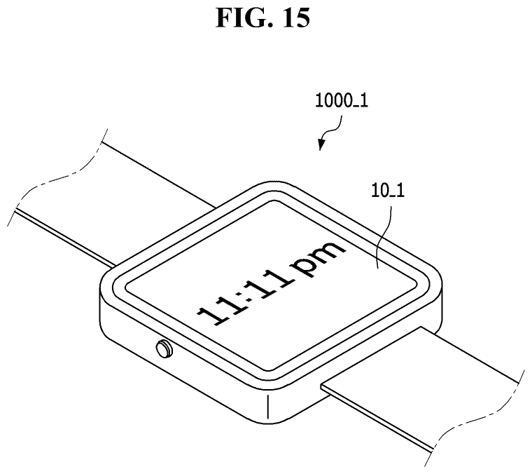

FIG. 15 is a diagram illustrating a smart watch including a display device according to an embodiment.

Referring to FIG. 15, a display device 10_1 according to an embodiment may be applied to a smart watch 1000_1 that is one of the smart devices.

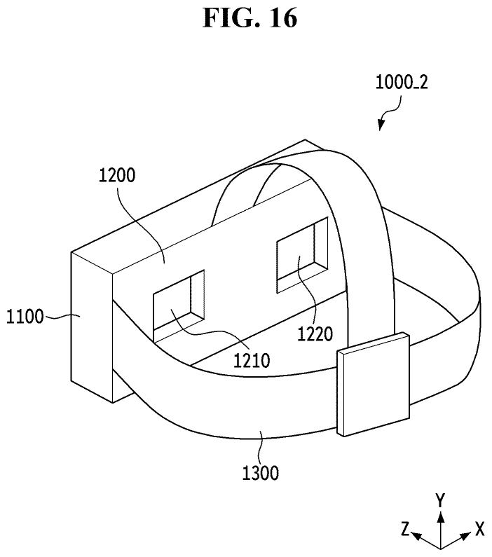

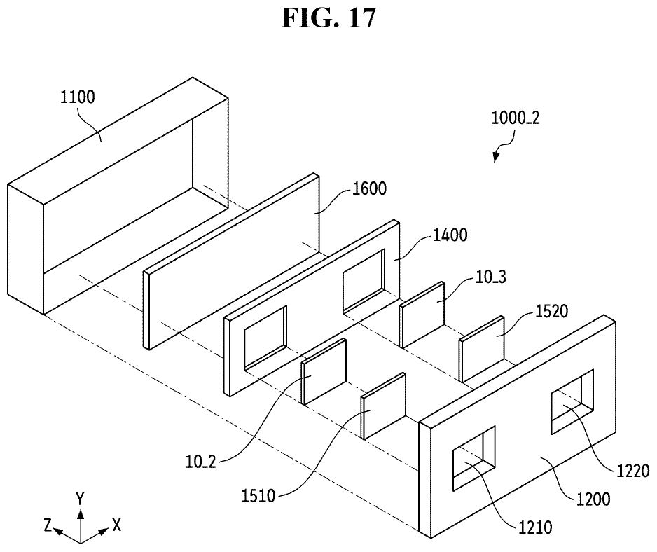

FIGS. 16 and 17 illustrate a head mounted display including a display device according to an embodiment.

Referring to FIGS. 16 and 17, a head mounted display 1000_2 according to an embodiment may be a virtual reality device. The head mounted display 1000_2 may include a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to the user's left eye, and the second display device 10_3 provides an image to the user's right eye.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and between the second display device 10_3 and the control circuit board 1600. The middle frame 1400 may serve to support and fix the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through the connector. The control circuit board 1600 may convert an image source inputted from the outside into video data, and transmit the video data to the first display device 10_2 and the second display device 10_3 through the connector.

The control circuit board 1600 may transmit the video data corresponding to a left-eye image optimized for the user's left eye to the first display device 10_2, and may transmit the video data corresponding to a right-eye image optimized for the user's right eye to the second display device 10_3. By way of example, the control circuit board 1600 may transmit the same video data to the first display device 10_2 and the second display device 10_3.

The display device housing 1100 may serve to accommodate the first display device 10_2, the second display device 10_3, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 16 and 17 illustrate that the first eyepiece 1210 and the second eyepiece 1220 are disposed separately, but the disclosure is not limited thereto. The first eyepiece 1210 and the second eyepiece 1220 may be combined into one.

The first eyepiece 1210 may be aligned with the first display device 10_2 and the first optical member 1510, and the second eyepiece 1220 may be aligned with the second display device 10_3 and the second optical member 1520. Therefore, the user may view, through the first eyepiece 1210, the image of the first display device 10_2 magnified as a virtual image by the first optical member 1510, and may view, through the second eyepiece 1220, the image of the second display device 10_3 magnified as a virtual image by the second optical member 1520.

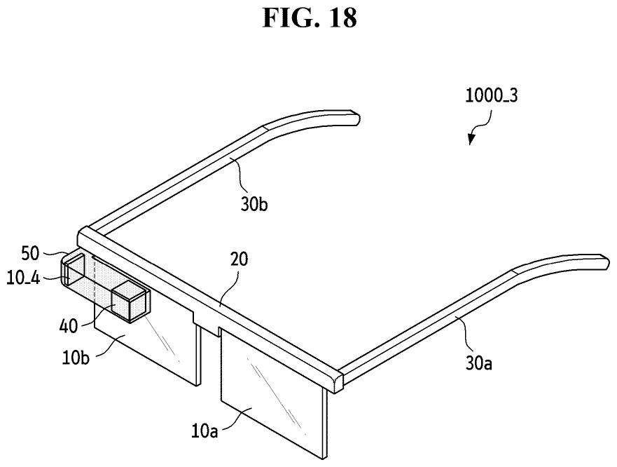

The head mounted band 1300 may serve to secure the display device housing 1100 to the user's head such that the first eyepiece 1210 and the second eyepiece 1220 of the housing cover 1200 remain located on the user's left and right eyes, respectively. In case that the display device housing 1100 is implemented to be lightweight and compact, the head mounted display 1000_2 may be provided with, as shown in FIG. 18, an eyeglass frame instead of the head mounted band 1300.

Additionally, the head mounted display 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module. FIG. 17 also illustrates non-limiting directions X, Y, and Z.

FIG. 18 illustrates a head mounted display including a display device according to an embodiment.

Referring to FIG. 18, a head mounted display 1000_3 according to an embodiment may be a glasses-type device. The head mounted display 1000_3 according to an embodiment may include a display device 10_4, a left eye lens 10a, a right eye lens 10b, a support frame 20, temples 30a and 30b, a reflection member 40, and a display device housing 50.

Although FIG. 18 illustrates the head-mounted display device 1000_3 as a glasses-type display device including temples 30a and 30b, the embodiments are not limited thereto. For example, the head-mounted display device 1000_3 may be applied in various forms in other electronic devices.

The display device housing 50 may include the display device 10_4 and the reflection member 40 (or an optical path changing member). An image displayed on the display device 10_4 may be reflected by the reflection member 40 and provided to the user's right eye through the right eye lens 10b. As a result, the user may view an augmented reality image, through the right eye, in which a virtual image displayed on the display device 10_4 and a real image seen through the right eye lens 10b are combined. In an embodiment, the display device housing 50 may further include an optical member disposed between the display device 10_4 and the reflection member 40. The image displayed on the display device 10_4 may be magnified by the optical member, and may be provided to the user's right eye through the right eye lens 10b after the optical path thereof is changed by the reflection member 40.

Although FIG. 18 illustrates that the display device housing 50 is disposed at the right end of the support frame 20, the embodiment of the specification is not limited thereto. For example, the display device housing 50 may be disposed at the left end of the support frame 20, and the image displayed on the display device 10_4 may be reflected by the reflection member 40 and provided to a user's left eye through the left eye lens 10a. As a result, the user may view the image displayed on the display device 10_4 with the left eye. By way of example, the display device housing 50 may be disposed at both the left end and the right end of the support frame 20, in which case the user can view the image displayed on the display device 10_4 through both the left eye and the right eye.

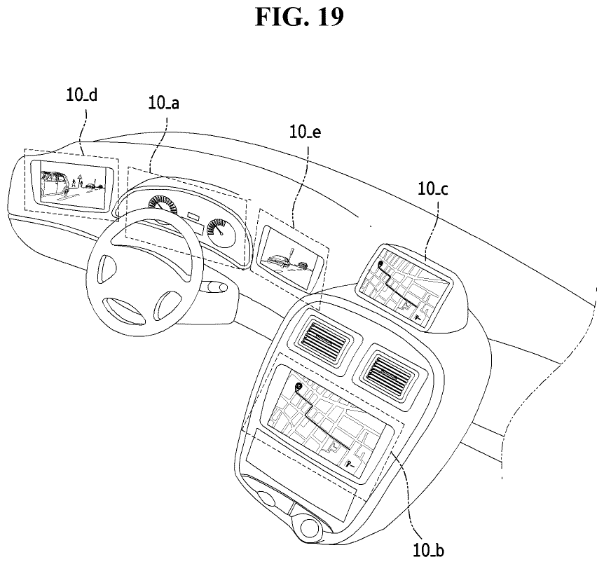

FIG. 19 is a diagram illustrating a dashboard of an automobile and a center fascia including display devices according to an embodiment. FIG. 19 illustrates a vehicle to which display devices 10_a, 10_b, 10_c, 10_d, and 10_e according to an embodiment are applied.

Referring to FIG. 19, the display devices 10_a, 10_b, and 10_c according to an embodiment may be applied to the dashboard of the automobile, the center fascia of the automobile, or the center information display (CID) of the dashboard of the automobile. Further, the display devices 10_d, and 10_e according to an embodiment may be applied to a room mirror display instead of side mirrors of the automobile.

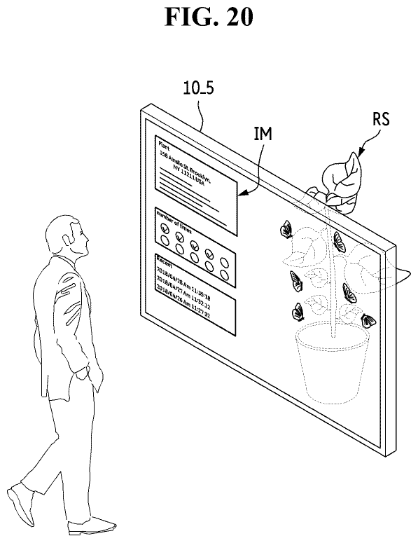

FIG. 20 is a diagram illustrating a transparent display device including a display device according to an embodiment.

Referring to FIG. 20, a display device 10_5 according to an embodiment may be applied to the transparent display device. The transparent display device may display an image IM, and also may transmit light. Thus, a user located on the front side of the transparent display device can view an object RS or a background on the rear side of the transparent display device as well as the image IM displayed on the display device 10_5. In case that the display device 10_5 is applied to the transparent display device, the substrate of the display device 10_5 may include a light transmitting portion capable of transmitting light or may be made of a material capable of transmitting light.

FIGS. 15 to 20 shows various examples of electronic devices that may include the display device 10 according to the previously described embodiments. However, the electronic devices that may include the display device 10 according to the embodiments are not limited to the electronic devices shown in FIGS. 15 to 20. For example, the display device 10 according to the embodiments may also be included in other types or structures of electronic devices and may be used as the display screen of the electronic device.

The electronic device may be at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A display device comprising:
a lower substrate;
a first bonding electrode disposed on the lower substrate;
a first light emitting element disposed on the first bonding electrode;
a second bonding electrode disposed on the first light emitting element; and
a second light emitting element disposed on the second bonding electrode,
wherein the second bonding electrode comprises a first distributed Bragg reflector including at least one pair of a first transparent conductive layer and a second transparent conductive layer having different refractive indices that are alternately stacked.

2. The display device of claim 1, wherein the first transparent conductive layer and the second transparent conductive layer include a same transparent conductive oxide, and
the second transparent conductive layer has a higher concentration of pores compared to pores of the first transparent conductive layer.

3. The display device of claim 2, wherein the first transparent conductive layer includes indium tin oxide (ITO), and
the second transparent conductive layer includes porous ITO.

4. The display device of claim 2, wherein the first transparent conductive layer includes zinc oxide (ZnO) or indium zinc oxide (IZO), and
the second transparent conductive layer includes porous ZnO or porous IZO.

5. The display device of claim 2, wherein the first transparent conductive layer and the second transparent conductive layer further include gallium doped into the same transparent conductive oxide.

6. The display device of claim 1, wherein the first light emitting element emits light of a first color,
the second light emitting element emits light of a second color, and
the first distributed Bragg reflector transmits light of the first color and reflects light of the second color.

7. The display device of claim 6, further comprising:
a third bonding electrode disposed on the second light emitting element; and
a third light emitting element disposed on the third bonding electrode,
wherein the third bonding electrode comprises a second distributed Bragg reflector including at least one pair of a third transparent conductive layer and a fourth transparent conductive layer having different refractive indices that are alternately stacked.

8. The display device of claim 7, wherein the third light emitting element emits light of a third color, and
the second distributed Bragg reflector transmits light of the first color and light of the second color and reflects light of the third color.

9. The display device of claim 8, wherein the third transparent conductive layer and the fourth transparent conductive layer include a same transparent conductive oxide, and
the fourth transparent conductive layer has a higher concentration of pores than pores of the third transparent conductive layer.

10. The display device of claim 9, wherein the third transparent conductive layer includes ITO, and
the fourth transparent conductive layer includes porous ITO.

11. The display device of claim 9, wherein the third transparent conductive layer includes ZnO or IZO, and
the fourth transparent conductive layer includes porous ZnO or porous IZO.

12. The display device of claim 9, wherein the third transparent conductive layer and the fourth transparent conductive layer further include gallium doped into the same transparent conductive oxide.

13. The display device of claim 9, wherein the second transparent conductive layer and the fourth transparent conductive layer are formed as porous films including the same transparent conductive oxide.

14. The display device of claim 13, wherein at least one of a porosity of the second transparent conductive layer and a porosity of the fourth transparent conductive layer, a number of pairs of the first transparent conductive layer and the second transparent conductive layer and a number of pairs of the third transparent conductive layer and the fourth transparent conductive layer, and a pair thickness of the first transparent conductive layer and the second transparent conductive layer and a pair thickness of the third transparent conductive layer and the fourth transparent conductive layer are different.

15. The display device of claim 1, wherein the first bonding electrode comprises a bonding metal layer including a bonding metal and a reflective layer disposed above the bonding metal layer.

16. The display device of claim 1, further comprising:
a first pixel electrode electrically connected to a first semiconductor layer of the first light emitting element through the first bonding electrode;
an interlayer insulating layer disposed between the first light emitting element and the second bonding electrode;
a second pixel electrode electrically connected to a first semiconductor layer of the second light emitting element through the second bonding electrode; and
a common electrode electrically connected to a second semiconductor layer of the first light emitting element and a second semiconductor layer of the second light emitting element.

17. The display device of claim 1, wherein the first light emitting element and the second light emitting element are connected to the second bonding electrode.

18. The display device of claim 17, further comprising:
a first pixel electrode electrically connected to a first semiconductor layer of the first light emitting element through the first bonding electrode;
a second pixel electrode electrically connected to a first semiconductor layer of the second light emitting element;
a common electrode electrically connected to a second semiconductor layer of the first light emitting element and a second semiconductor layer of the second light emitting element through the second bonding electrode; and
a connection electrode disposed on the second light emitting element and electrically connecting the first semiconductor layer of the second light emitting element to the second pixel electrode.

19. An electronic device including a display device, the display device comprising:
a lower substrate;
a first bonding electrode disposed on the lower substrate;
a first light emitting element disposed on the first bonding electrode;
a second bonding electrode disposed on the first light emitting element; and
a second light emitting element disposed on the second bonding electrode,
wherein the second bonding electrode comprises a first distributed Bragg reflector including at least one pair of a first transparent conductive layer and a second transparent conductive layer having different refractive indices that are alternately stacked.

20. The electronic device of claim 19, wherein the first transparent conductive layer and the second transparent conductive layer include a same transparent conductive oxide,
the second transparent conductive layer has a higher concentration of pores compared to pores of the first transparent conductive layer,
the first transparent conductive layer includes indium tin oxide (ITO), and
the second transparent conductive layer includes porous ITO.
